(19) United States
(12) Patent Application Publication
(10) Pub. No.: US 2019/0051703 A1
(43) Pub. Date: Feb. 14, 2019

(54) TWO-DIMENSIONAL ARRAY OF SURROUND GATE VERTICAL FIELD EFFECT TRANSISTORS AND METHOD OF MAKING THEREOF

(71) Applicant: SANDISK TECHNOLOGIES LLC, PLANO, TX (US)

(72) Inventors: Jongsun SEL, Los Gatos, CA (US); Hisakazu OTOI, Yokkaichi (JP); Seje TAKAKI, Yokkaichi (JP); Tuan PHAM, San Jose, CA (US)

(21) Appl. No.: 15/672,929

(22) Filed: Aug. 9, 2017

(51) Int. Cl. H01L 27/24; H01L 21/8234; H01L 29/10; H01L 29/423

(52) U.S. Cl. CPC H01L 27/2454; H01L 29/42356; H01L 29/1037; H01L 21/823487

(57) ABSTRACT

A two-dimensional array of vertical field effect transistors is provided, which includes a one-dimensional array of ladder-shaped gate electrode lines. Each of the ladder-shaped gate electrode lines includes a pair of rail portions that laterally extend along a first horizontal direction and spaced among one another along a second horizontal direction and rung portions extending between the pair of rail portions along the second horizontal direction. The vertical field effect transistors include gate dielectrics located in each opening defined by a neighboring pair of rung portions, and vertical semiconductor channels laterally surrounded by a respective one of the gate dielectrics and extending along a vertical direction. The two-dimensional array of vertical field effect transistors can be employed to select vertical bit lines of a three-dimensional ReRAM device.

### FIELD

The present disclosure relates generally to the field of semiconductor devices and specifically to a two-dimensional array of surround gate field effect transistors and methods of manufacturing the same.

### BACKGROUND

Resistive Random Access Memory, or “ReRAM,” is a non-volatile memory device employing reversible change in resistance in a thin film with application of electrical voltage bias across the film. Thus, data can be stored in a ReRAM cell by changing the resistance of the thin film, which can be a solid-state material. The thin film is referred to as a memory film or a read/write film. Examples of ReRAM devices are described in World Intellectual Property Organization (WIPO) Publication No. WO2007004843 A1 to Hong et al. and U.S. Patent Application Publication No. 2013/0043455 A1 to Bateman A resistive memory cell can be programmed into a set state having a low electrical resistance, or a reset state having a high resistance. A write operation stores data in a set of resistive memory cells by programming each resistive memory cell into a set state or a reset state depending on the contents of the data. For example, “1” can correspond to a set state and “0” can correspond to a reset state, or vice versa.

### SUMMARY

According to an aspect of the present disclosure, a semiconductor structure comprising a two-dimensional array of vertical field effect transistors is provided. The two-dimensional array of vertical field effect transistors comprises: a one-dimensional array of ladder-shaped gate electrode lines, wherein each of the ladder-shaped gate electrode lines comprises a pair of rail portions that laterally extend along a first horizontal direction and spaced among one another along a second horizontal direction and rung portions extending between the pair of rail portions along the second horizontal direction; gate dielectrics located in each opening defined by a neighboring pair of rung portions; and vertical semiconductor channels laterally surrounded by a respective one of the gate dielectrics and extending along a vertical direction.

According to another aspect of the present disclosure, a method of forming a semiconductor structure is provided. A stack of a doped semiconductor material layer having a doping of a first conductivity type, a planar insulating spacer layer, and a gate conductor material layer are sequentially formed. Gate divider rail structures are formed through the gate conductor material layer. The gate divider rail structures laterally extend along a first horizontal direction and laterally spaced among one another along a second horizontal direction. Remaining portions of the gate conductor material layer include gate conductor rails that are laterally separated among one another by the gate divider rail structures. Rectangular openings are formed in each of the gate conductor rails. Gate dielectrics are formed on sidewalls of the rectangular openings. Vertical semiconductor channels are formed within each of the gate dielectrics by deposition of a semiconductor material having a doping of a second conductivity type that is different from the first conductivity type.

### BRIEF DESCRIPTION OF THE DRAWINGS

FIG. 1A is a top-down view of a first exemplary structure after formation of a layer stack including a conductive material layer, a metal nitride layer, a doped semiconductor layer, and an planar insulating spacer layer according to a first embodiment of the present disclosure.

FIG. 1B is a vertical cross-sectional view of the first exemplary structure along the vertical plane B-B′ of FIG. 1A.

FIG. 2A is a top-down view of the first exemplary structure after formation of an alternating sequence of conductive rails and dielectric separator rails that alternate along a second horizontal direction according to the first embodiment of the present disclosure.

FIG. 2B is a vertical cross-sectional view of the first exemplary structure along the vertical plane B-B′ of FIG. 2A.

FIG. 3A is a top-down view of the first exemplary structure after formation of a gate conductor material layer, a dielectric cap layer, a sacrificial matrix layer, and a hard mask layer according to the first embodiment of the present disclosure.

FIG. 3B is a vertical cross-sectional view of the first exemplary structure along the vertical plane B-B′ of FIG. 3A.

FIG. 4A is a top-down view of the first exemplary structure after application and patterning of a first photoresist layer according to the first embodiment of the present disclosure.

FIG. 4B is a vertical cross-sectional view of the first exemplary structure along the vertical plane B-B′ of FIG. 4A.

FIG. 5A is a top-down view of the first exemplary structure after patterning the hard mask layer and the sacrificial matrix layer to form first line trenches, hard mask strips, and sacrificial material strips, and formation of self-aligned disposable spacers according to the first embodiment of the present disclosure.

FIG. 5B is a vertical cross-sectional view of the first exemplary structure along the vertical plane B-B′ of FIG. 5A.

FIG. 6A is a top-down view of the first exemplary structure after formation of second line trenches, dielectric cap structures, and gate conductor rails according to the first embodiment of the present disclosure.

FIG. 6B is a vertical cross-sectional view of the first exemplary structure along the vertical plane B-B′ of FIG. 6A.

FIG. 7A is a top-down view of the first exemplary structure after formation of gate divider rail structures according to the first embodiment of the present disclosure.

FIG. 7B is a vertical cross-sectional view of the first exemplary structure along the vertical plane B-B′ of FIG. 7A.

FIG. 8A is a top-down view of the first exemplary structure after removal of the hard mask strips according to the first embodiment of the present disclosure.

FIG. 8B is a vertical cross-sectional view of the first exemplary structure along the vertical plane B-B′ of FIG. 8A.

FIG. 9A is a top-down view of the first exemplary structure after application and patterning of a second photoresist layer according to the first embodiment of the present disclosure.

FIGS. 9B, 9C, and 9D are vertical cross-sectional views of the first exemplary structure along the vertical planes B-B′, C-C′, and D-D′, respectively, of FIG. 9A.

FIG. 10A is a top-down view of the first exemplary structure after an anisotropic etch that patterns the sacrificial material strips into sacrificial material portions, and patterns the dielectric cap structures with rectangular openings according to the first embodiment of the present disclosure.

FIGS. 10B, 10C, 10D, 10E, and 10F are vertical cross-sectional views of the first exemplary structure along the vertical planes B-B′, C-C′, D-D′, E-E′, and F-F′, respectively, of FIG. 10A.

FIG. 11A is a top-down view of the first exemplary structure after removal of the second photoresist layer according to the first embodiment of the present disclosure.

FIGS. 11B, 11C, 11D, 11E, and 11F are vertical cross-sectional views of the first exemplary structure along the vertical planes B-B′, C-C′, D-D′, E-E′, and F-F′, respectively, of FIG. 11A.

FIG. 12A is a top-down view of the first exemplary structure after an anisotropic etch that removes the sacrificial material portions and patterns the gate conductor rails into ladder-shaped gate electrode lines according to the first embodiment of the present disclosure.

FIGS. 12B, 12C, 12D, 12E, and 12F are vertical cross-sectional views of the first exemplary structure along the vertical planes B-B′, C-C′, D-D′, E-E′, and F-F′, respectively, of FIG. 12A.

FIGS. 12G, 12H, and 12I are horizontal cross-sectional views of the first exemplary structure of FIGS. 12A-12F along the horizontal planes G-G′, H-H′, and I-I′, respectively, of FIGS. 12B and 12D.

FIG. 13A is a top-down view of the first exemplary structure after formation of gate dielectrics and first vertical channel portions according to the first embodiment of the present disclosure.

FIGS. 13B and 13C are vertical cross-sectional views of the first exemplary structure along the vertical planes B-B′ and C-C′, respectively, of FIG. 13A.

FIGS. 13D, 13E, and 13F are horizontal cross-sectional views of the first exemplary structure of FIGS. 13A-13C along the horizontal planes D-D′, E-E′, and F-F′, respectively, of FIGS. 13B and 13C.

FIG. 14A is a top-down view of the first exemplary structure after formation of second vertical channel portions according to the first embodiment of the present disclosure.

FIGS. 14B and 14C are vertical cross-sectional views of the first exemplary structure along the vertical planes B-B′ and C-C′, respectively, of FIG. 14A.

FIG. 14D is a horizontal cross-sectional view of the first exemplary structure of FIGS. 14A-14C along the horizontal plane D-D′, of FIGS. 14B and 14C.

FIG. 15A is a top-down view of the first exemplary structure after formation of top active regions by ion implantation according to the first embodiment of the present disclosure.

FIGS. 15B and 15C are vertical cross-sectional views of the first exemplary structure along the vertical planes B-B′ and C-C′, respectively, of FIG. 15A.

FIG. 15D is a horizontal cross-sectional view of the first exemplary structure of FIGS. 15A-15C along the horizontal plane D-D′, of FIGS. 15B and 15C.

FIG. 16A is a top-down view of the first exemplary structure after formation of bottom active regions and expansion of top active regions by performing an anneal process according to the first embodiment of the present disclosure.

FIGS. 16B and 16C are vertical cross-sectional views of the first exemplary structure along the vertical planes B-B′ and C-C′, respectively, of FIG. 16A.

FIG. 16D is a horizontal cross-sectional view of the first exemplary structure of FIGS. 16A-16C along the horizontal plane D-D′, of FIGS. 16B and 16C.

FIG. 17 is a vertical cross-sectional view of the first exemplary structure after formation of a plurality of alternating stacks of insulating strips and electrically conductive strips over the two-dimensional array of vertical field effect transistors, resistive memory elements, and vertical bit lines according to the first embodiment of the present disclosure.

FIG. 18A is a top-down view of a second exemplary structure after formation of a layer stack including a conductive material layer, a metal nitride layer, a doped semiconductor layer, and a sacrificial pad layer according to a second embodiment of the present disclosure.

FIG. 18B is a vertical cross-sectional view of the second exemplary structure along the vertical plane B-B′ of FIG. 18A.

FIG. 19A is a top-down view of the second exemplary structure after formation of an alternating sequence of conductive rails and dielectric separator rails that alternate along a second horizontal direction according to the second embodiment of the present disclosure.

FIG. 19B is a vertical cross-sectional view of the second exemplary structure along the vertical plane B-B′ of FIG. 19A.

FIG. 20A is a top-down view of the second exemplary structure after recessing the dielectric separator rails according to the second embodiment of the present disclosure.

FIG. 20B is a vertical cross-sectional view of the second exemplary structure along the vertical plane B-B′ of FIG. 20A.

FIG. 21A is a top-down view of the second exemplary structure after formation of an planar insulating spacer layer according to the second embodiment of the present disclosure.

FIG. 21B is a vertical cross-sectional view of the second exemplary structure along the vertical plane B-B′ of FIG. 21A.

FIG. 22A is a top-down view of the second exemplary structure after formation of a gate conductor material layer, a dielectric cap layer, a sacrificial matrix layer, a first hard mask layer, and a second hard mask layer according to the second embodiment of the present disclosure.

FIG. 22B is a vertical cross-sectional view of the second exemplary structure along the vertical plane B-B′ of FIG. 22A.

FIG. 23A is a top-down view of the second exemplary structure after application and patterning of a first photoresist layer and transfer of the pattern into the second hard mask layer, the first hard mask layer, and the sacrificial matrix layer to form first line trenches according to the second embodiment of the present disclosure.

FIG. 23B is a vertical cross-sectional view of the second exemplary structure along the vertical plane B-B′ of FIG. 23A.

FIG. 24A is a top-down view of the second exemplary structure after removal of the first photoresist layer and formation of self-aligned disposable spacers according to the second embodiment of the present disclosure.

FIG. 24B is a vertical cross-sectional view of the second exemplary structure along the vertical plane B-B′ of FIG. 24A.

FIG. 25A is a top-down view of the second exemplary structure after formation of second line trenches, dielectric cap structures, and gate conductor rails according to the second embodiment of the present disclosure.

FIG. 25B is a vertical cross-sectional view of the second exemplary structure along the vertical plane B-B′ of FIG. 25A.

FIG. 26A is a top-down view of the second exemplary structure after formation of gate divider rail structures and removal of remaining portions of the second hard mask layer according to the second embodiment of the present disclosure.

FIG. 26B is a vertical cross-sectional view of the second exemplary structure along the vertical plane B-B′ of FIG. 26A.

FIG. 27A is a top-down view of the second exemplary structure after removal of remaining portions of the first hard mask layer and the sacrificial matrix layer according to the second embodiment of the present disclosure.

FIG. 27B is a vertical cross-sectional view of the second exemplary structure along the vertical plane B-B′ of FIG. 27A.

FIG. 28A is a top-down view of the second exemplary structure after application and patterning of a second photoresist layer according to the second embodiment of the present disclosure.

FIGS. 28B, 28C, and 28D are vertical cross-sectional views of the second exemplary structure along the vertical planes B-B′, C-C′, and D-D′, respectively, of FIG. 28A.

FIG. 29A is a top-down view of the second exemplary structure after an anisotropic etch that patterns the dielectric cap structures with rectangular openings and patterns the gate conductor rails into ladder-shaped gate electrode lines according to the second embodiment of the present disclosure.

FIGS. 29B, 29C, 29D, 29E, and 29F are vertical cross-sectional views of the second exemplary structure along the vertical planes B-B′, C-C′, D-D′, E-E′, and F-F′, respectively, of FIG. 29A.

FIGS. 29G and 29H are horizontal cross-sectional views of the second exemplary structure of FIGS. 29A-29F along the horizontal planes G-G′ and H-H′, respectively, of FIGS. 29D, 29E and 29F.

FIG. 30A is a top-down view of the second exemplary structure after removal of the second photoresist layer according to the second embodiment of the present disclosure.

FIGS. 30B, 30C, 30D, 30E, and 30F are vertical cross-sectional views of the second exemplary structure along the vertical planes B-B′, C-C′, D-D′, E-E′, and F-F′, respectively, of FIG. 30A.

FIG. 31A is a top-down view of the second exemplary structure after formation of sacrificial pillar structures according to the second embodiment of the present disclosure.

FIGS. 31B, 31C, 31D, 31E, and 31F are vertical cross-sectional views of the second exemplary structure along the vertical planes B-B′, C-C′, D-D′, E-E′, and F-F′, respectively, of FIG. 31A.

FIG. 32A is a top-down view of the second exemplary structure after removal of protruding structures above the dielectric cap structures by a planarization process and removal of the sacrificial pillar structures according to the second embodiment of the present disclosure.

FIGS. 32B, 32C, 32D, 32E, and 32F are vertical cross-sectional views of the second exemplary structure along the vertical planes B-B′, C-C′, D-D′, E-E′, and F-F′, respectively, of FIG. 32A.

FIG. 33A is a top-down view of the second exemplary structure after formation of gate dielectrics and first vertical channel portions and formation of openings through the planar insulating spacer layer according to the second embodiment of the present disclosure.

FIGS. 33B, 33C, 33D, 33E, and 33F are vertical cross-sectional views of the second exemplary structure along the vertical planes B-B′, C-C′, D-D′, E-E′, and F-F′, respectively, of FIG. 33A.

FIGS. 33G and 33H are horizontal cross-sectional views of the second exemplary structure along the horizontal planes G-G′ and H-H′, respectively, of FIG. 33D.

FIG. 34A is a top-down view of the second exemplary structure after formation of a second vertical channel layer according to the second embodiment of the present disclosure.

FIGS. 34B, 34C, 34D, 34E, and 34F are vertical cross-sectional views of the second exemplary structure along the vertical planes B-B′, C-C′, D-D′, E-E′, and F-F′, respectively, of FIG. 34A.

FIG. 35A is a top-down view of the second exemplary structure after formation of dielectric cores, removal of top horizontal portions of the second vertical channel layer to form second vertical channel portions, and vertical recessing of the dielectric cores according to the second embodiment of the present disclosure.

FIGS. 35B, 35C, 35D, 35E, and 35F are vertical cross-sectional views of the second exemplary structure along the vertical planes B-B′, C-C′, D-D′, E-E′, and F-F′, respectively, of FIG. 35A.

FIG. 36A is a top-down view of the second exemplary structure after formation of top active regions according to the second embodiment of the present disclosure.

FIGS. 36B, 36C, 36D, 36E, and 36F are vertical cross-sectional views of the second exemplary structure along the vertical planes B-B′, C-C′, D-D′, E-E′, and F-F′, respectively, of FIG. 36A.

FIG. 37A is a top-down view of the second exemplary structure after formation of bottom active regions and expansion of top active regions by performing an anneal process according to the second embodiment of the present disclosure.

FIGS. 37B, 37C, 37D, 37E, and 37F are vertical cross-sectional views of the second exemplary structure along the vertical planes B-B′, C-C′, D-D′, E-E′, and F-F′, respectively, of FIG. 37A.

FIG. 38 is a vertical cross-sectional view of the second exemplary structure after formation of a plurality of alternating stacks of insulating strips and electrically conductive strips over the two-dimensional array of vertical field effect transistors, resistive memory elements, and vertical bit lines according to the second embodiment of the present disclosure.

### DETAILED DESCRIPTION

Resistive memory cells of a ReRAM memory device can be arranged in a three-dimensional array that is accessed by a two-dimensional array of vertical bit lines. A two-dimensional array of vertical select field effect transistors can be connected to the two-dimensional array of vertical bit lines to access the resistive memory cells. The present inventors realized that conventional vertical select field effect transistors may contain suboptimum on current and leakage current. Such vertical field effect transistors typically have a dual channel configuration, in which each vertical channel is controlled by a pair of gate electrodes. Typically, each vertical channel has a rectangular horizontal cross-sectional shape, and the pair of gate electrodes controls electron flow along two sidewalls of a rectangular pillar that constitutes the vertical channel Current flow along the other two sidewalls of the rectangular pillar is only indirectly controlled by the pair of gate electrodes in this configuration. Thus, leakage current and degradation of turn-on characteristics are common in such configurations. In one embodiment of the present disclosure, the vertical select field effect transistor contains a ladder shaped surround select gate electrode which surrounds the entire channel. This configuration can improve the on current of the transistor

As discussed above, the present disclosure is directed to a two-dimensional array of surround gate field effect transistors and methods of manufacturing the same, the various aspects of which are described below. The embodiments of the disclosure can be employed to form various semiconductor devices, such as three-dimensional monolithic memory array devices comprising ReRAM devices, that include a two-dimensional array of vertical field effect select transistors. The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow. As used herein, a “layer stack” refers to a stack of layers. As used herein, a “line” or a “line structure” refers to a layer that has a predominant direction of extension, i.e., having a direction along which the layer extends the most.

As used herein, a “field effect transistor” refers to any semiconductor device having a semiconductor channel through which electrical current flows with a current density modulated by an external electrical field. As used herein, an “active region” refers to a source region of a field effect transistor or a drain region of a field effect transistor. A “top active region” refers to an active region of a field effect transistor that is located above another active region of the field effect transistor. A “bottom active region” refers to an active region of a field effect transistor that is located below another active region of the field effect transistor.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “resistive memory material” or a “reversibly resistance-switching material” is a material of which the resistivity can be altered by application of a voltage across the material. As used herein, a “resistive memory material layer” refers to a layer including a resistive memory material. As used herein, a “resistive memory element” refers to an element that includes a portion of a resistive memory material in a configuration that enables programming of the resistive memory material into at least two states having different values of electrical resistance.

A monolithic three dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two-dimensional arrays may be formed separately and then packaged together to form a non-monolithic memory device. For example, non-monolithic stacked memories have been constructed by forming memory levels on separate substrates and vertically stacking the memory levels, as described in U.S. Pat. No. 5,915,167 titled “Three Dimensional Structure Memory.” The substrates may be thinned or removed from the memory levels before bonding, but as the memory levels are initially formed over separate substrates, such memories are not true monolithic three dimensional memory arrays.

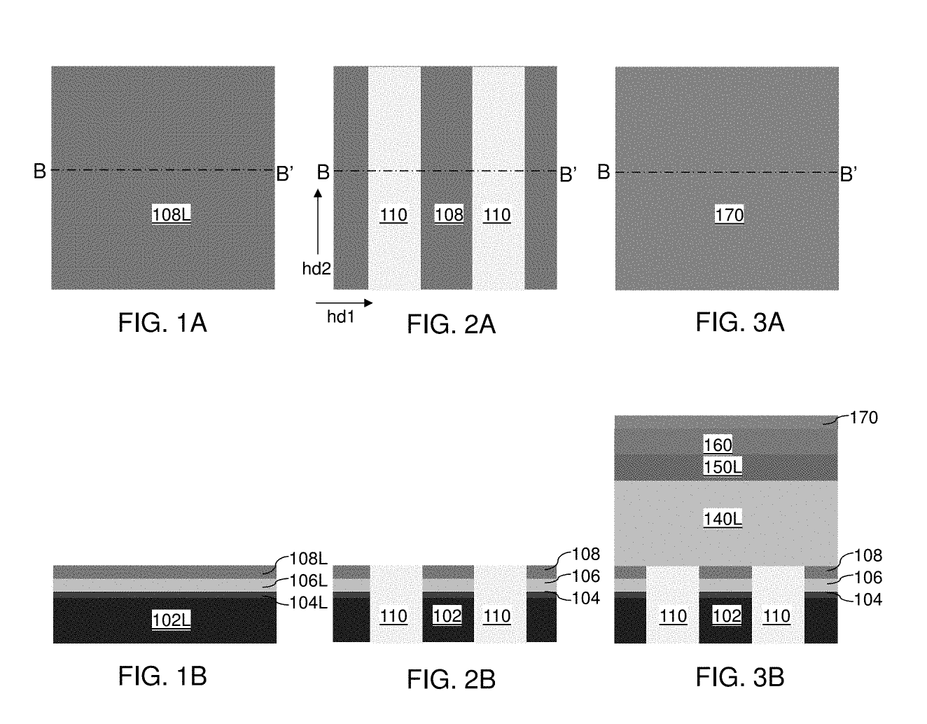

Referring to FIGS. 1A and 1B, a first exemplary structure is illustrated, which includes a layer stack (102L, 104L, 106L, 108L) that can be formed on a top surface of a substrate (not shown) including an insulating top surface. The layer stack (102L, 104L, 106L, 108L) includes a conductive material layer 102L, an optional metal nitride layer 104L, a doped semiconductor layer 106L, and a planar insulating spacer layer 108L. The doped semiconductor material layer 106L can be formed over, and can be electrically shorted to, the conductive material layer 102L. In an illustrative example, the conductive material layer 102L can include tungsten or copper; the optional metal nitride layer 104L can include titanium nitride, tantalum nitride layer, or tungsten nitride layer; the doped semiconductor layer 106L can include doped polysilicon or doped amorphous silicon (that can be subsequently converted into doped polysilicon through an anneal) having a doping of a first conductivity type (which can be p-type or n-type); and the planar insulating spacer layer 108L can include silicon nitride or silicon oxynitride. The thickness of the conductive material layer 102L can be in a range from 50 nm to 300 nm, the thickness of the optional metal nitride layer 104L can be in a range from 3 nm to 30 nm, the thickness of the doped semiconductor layer 106L can be in a range from 10 nm to 40 nm, and the thickness of the planar insulating spacer layer 108L can be in a range from 4 nm to 40 nm, although lesser and greater thicknesses can be employed for each layer.

Referring to FIGS. 2A and 2B, line trenches are formed through the layer stack (102L, 104L, 106L, 108L), for example, by applying and patterning a photoresist layer (not shown) over the layer stack (102L, 104L, 106L, 108L) and transferring the pattern in the photoresist layer through the (102L, 104L, 106L, 108L) by at least one anisotropic etch process. The line trenches laterally spaced among one another along a first horizontal direction hd1 and laterally extend along a second horizontal direction hd2 (i.e., global bit line direction) that is perpendicular to the first horizontal direction hd1. As used herein, a “line trench” refers to an elongated trench having a uniform width along a direction perpendicular to the lengthwise direction thereof. A top surface of an underlying substrate can be physically exposed at the bottom of each line trench. At least one dielectric material (such as a combination of a silicon nitride liner and a silicon oxide fill material) can be deposited in the line trenches, and excess portions of the at least one dielectric material can be removed from the horizontal plane including the top surface of the planar insulating spacer layer 108L by a planarization process (such as a chemical mechanical planarization process or a recess etch process).

Remaining portions of the at least one dielectric material constitute dielectric separator rails 110. As used herein, a “rail” refers to a structure that laterally extends in a lengthwise direction. In one non-limiting embodiment, a rail can extend with a uniform vertical cross-sectional shape along the vertical planes that are perpendicular to the lengthwise direction of the structure. Each remaining portion of the conductive material layer 102L constitutes a conductive rail 102 that laterally extends along the second horizontal direction hd2. An alternating sequence of conductive rails 102 and dielectric separator rails 110 that alternate along the second horizontal direction hd2 is formed. Each remaining portion of the metal nitride layer 104L constitutes a metal nitride strip 104 that laterally extends along the second horizontal direction hd2 and has a uniform width along the first horizontal direction hd1. Each combination of a conductive rail 102 and optional overlying metal nitride strip 104 can correspond to a global bit line of a ReRAM device. The alternating sequence of conductive rails 102 and dielectric separator rails 110 can have a pitch in a range from 50 nm to 400 nm along the first horizontal direction hd1, although lesser and greater pitches can also be employed. The width of the conductive rails 102 can be in a range from 20% to 80% of the pitch. The width of the dielectric separator rails 110 can be in a range from 20% to 80% of the pitch.

Each remaining portion of the doped semiconductor layer 106L constitutes a doped semiconductor strip 106, which is a doped semiconductor layer having a finite width. Specifically, each doped semiconductor strip 106 laterally extends along the second horizontal direction hd2 and has the uniform width along the first horizontal direction hd1. Each doped semiconductor strip 106 may comprise a global source or drain region of a ReRAM device. Each remaining portion of the planar insulating spacer layer 108L constitutes a planar insulating spacer strip 108 that laterally extends along the second horizontal direction hd2 and has the uniform width along the first horizontal direction hd1.

Referring to FIGS. 3A and 3B, a gate conductor material layer 140L, a dielectric cap layer 150L, a sacrificial matrix layer 160, and a hard mask layer 170 can be sequentially formed. The gate conductor material layer 140L includes a conductive material that is subsequently patterned into gate electrode lines. The gate conductor material layer 140L can include a doped semiconductor material (such as doped polysilicon or an amorphous doped polysilicon that can be subsequently annealed into doped polysilicon) or a metallic material (such as a conductive metal nitride, an elemental metal, or an intermetallic alloy). For example, the gate conductor material layer 140L can include doped polysilicon. The thickness of the gate conductor material layer 140L can be in a range from 100 nm to 500 nm, such as from 150 nm to 250 nm, although lesser and greater thicknesses can also be employed.

The dielectric cap layer 150L includes a dielectric material that subsequently provides vertical electrical insulation between the gate electrode lines to be formed and structures to be formed thereabove. For example, the dielectric cap layer 150L can include silicon oxide. The thickness of the dielectric cap layer 150L can be in a range from 30 nm to 120 nm, such as from 50 nm to 70 nm, although lesser and greater thicknesses can also be employed.

The sacrificial matrix layer 160 includes a sacrificial material (a material that is subsequently removed) that functions as a matrix for forming self-aligned spacers in subsequent processing steps. The sacrificial matrix layer 160 can include a material that can be removed selective to the material of the dielectric cap layer 150L. For example, the sacrificial matrix layer 160 can include silicon or a silicon-germanium alloy, which may, or may not, be doped with electrical dopants, and may be amorphous or polycrystalline. In one embodiment, the sacrificial matrix layer 160 can include undoped amorphous silicon. The thickness of the sacrificial matrix layer 160 can be in a range from 20 nm to 60 nm, such as from 30 nm to 40 nm, although lesser and greater thicknesses can also be employed.

The hard mask layer 170 includes a hard mask material that can be subsequently employed as a planarization stopping layer during a chemical mechanical planarization process. For example, the hard mask layer 170 can include silicon nitride. The thickness of the hard mask layer 170 can be in a range from 20 nm to 50 nm, although lesser and greater thicknesses can also be employed.

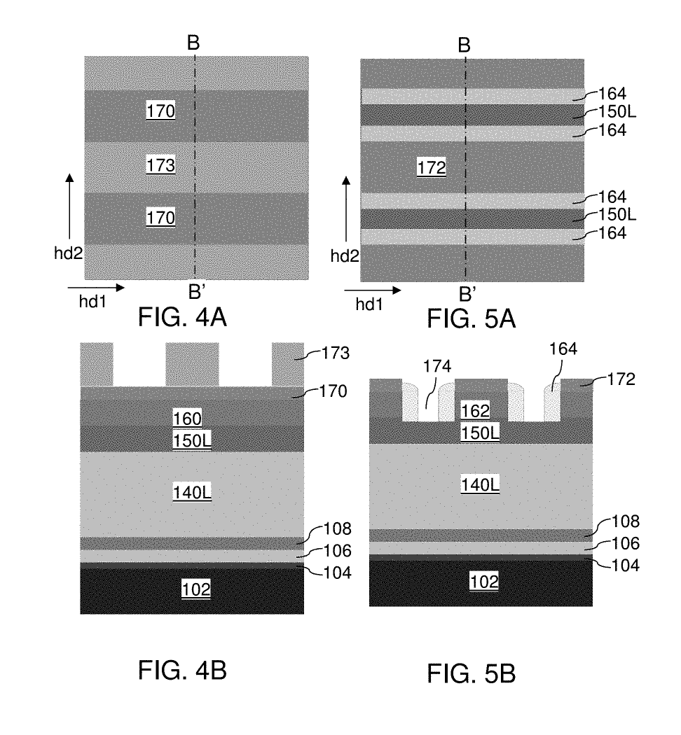

Referring to FIGS. 4A and 4B, a first photoresist layer 173 is applied over the hard mask layer 170, and is lithographically patterned with a line pattern. Line trenches laterally extending along a direction that is perpendicular to the lengthwise directions of the conductive rails 102 and the dielectric separator rails 110 are formed. For example, the line trenches in the patterned first photoresist layer 173 can laterally extend along the first horizontal direction hd1, and can be laterally spaced among one another along the second horizontal direction hd2. The patterned first photoresist layer 173 can have a pitch in a range from 50 nm to 400 nm along the second horizontal direction hd2, although lesser and greater pitches can also be employed.

Referring to FIGS. 5A and 5B, an anisotropic etch is performed to transfer the pattern of the first photoresist layer 173 through the hard mask layer 170 and the sacrificial matrix layer 160. The anisotropic etch can stop on the dielectric cap layer 150L. Line trenches 174 are formed through the stack of the sacrificial matrix layer 160 and the hard mask layer 170, which are herein referred to as first line trenches 174. Each remaining portion of the sacrificial matrix layer 160 is herein referred to as a sacrificial material strip 162. Each remaining portion of the hard mask layer 170 is herein referred to as hard mask strips 172. The first line trenches can laterally extend along the first horizontal direction hd1, and can be arranged as a one-dimensional periodic array that is repeated along the second horizontal direction with a pitch, which may be in a range from 50 nm to 400 nm. The width of each first line trench may be in a range from 20% to 80% of the pitch of the first line trenches along the second horizontal direction. The patterned first photoresist layer 173 can be subsequently removed, for example, by ashing.

Disposable spacers 164 can be formed on sidewalls of the first line trenches by depositing and anisotropically etching a conformal disposable material layer. As used herein, a “disposable material” is a material that is subsequently disposed of, i.e., removed. In one embodiment, the disposable spacers 164 can include silicon oxide or an organosilicate glass. The disposable spacers 164 are self-aligned to the sidewalls of the first line trenches, and thus, are self-aligned disposable spacers. As such, pairs of disposable spacers 164 constitute a one-dimensional periodic array along the second horizontal direction hd2 having a same pitch as the pitch of the first line trenches. The width of each disposable spacer 164 may be in a range from 5% to 45% of the width of a line trench. A cavity is laterally enclosed by each disposable spacer 164.

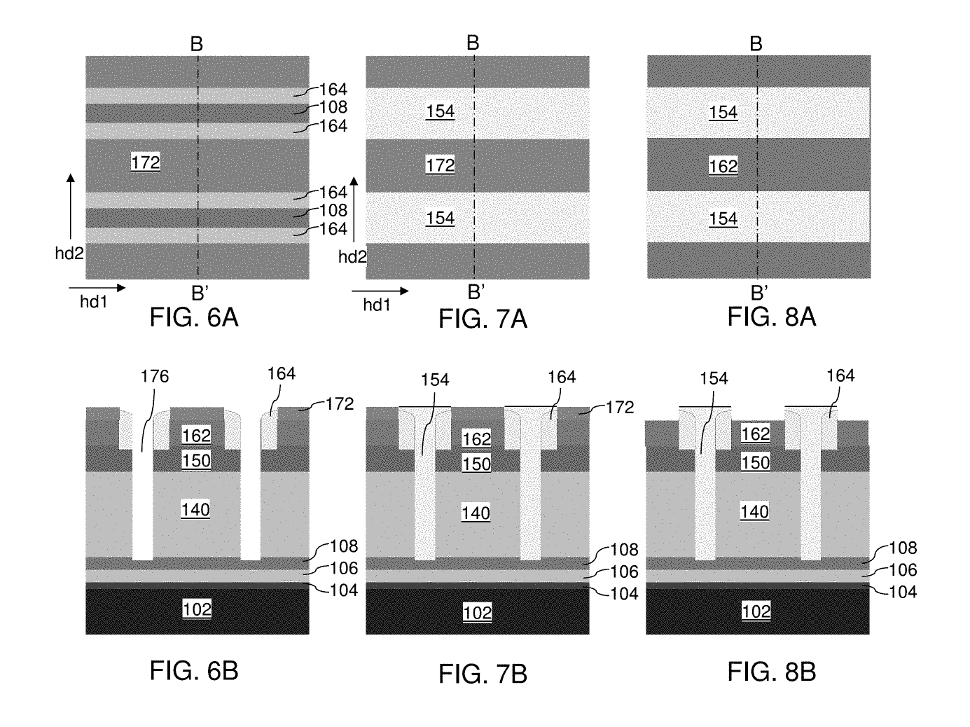

Referring to FIGS. 6A and 6B, an anisotropic etch is performed to transfer the pattern of each cavity within the disposable spacers 164 through the dielectric cap layer 150L and the gate conductor material layer 140L. The anisotropic etch process can include a first step that etches the material of the dielectric cap layer 150L selective to the material of the hard mask strips 172, and a second step that etches the material of the gate conductor material layer 140L selective to the materials of the hard mask strips 172 and the disposable spacers 164. Second line trenches 176 are formed through the gate conductor material layer 140L in areas that are not covered by remaining portions of the hard mask layer 170 (i.e., the hard mask strips 172) or the disposable spacers 164. The second line trenches 176 laterally extend along the first horizontal direction hd1, and are laterally spaced among one another along the second horizontal direction hd2. Remaining portions of the gate conductor material layer 140L include gate conductor rails 140 that may have a respective uniform width (along the second horizontal direction hd2) throughout, and are laterally separated among one another by the second line trenches 176. Remaining portions of the dielectric cap layer 150L include dielectric cap structures 150 that have the same width as a respective underlying gate conductor rail 140, and are laterally spaced among one another by the second line trenches 176.

Referring to FIGS. 7A and 7B, a dielectric material such as silicon oxide is deposited in the second line trenches 176. The dielectric material can be deposited by a conformal deposition process such as low pressure chemical vapor deposition (LPCVD) or spin-coating. Excess portions of the dielectric material can be removed from above the horizontal plane including the top surfaces of the hard mask strips 172, for example, by chemical mechanical planarization (CMP). The hard mask strips 172 can be employed as stopping structures during the CMP process. The remaining portions of the dielectric material in the second line trenches 176 constitute a dielectric rail structure, which is herein referred to as gate divider rail structures 154. Each gate divider rail structure 154 is formed within the volume of a respective one of the second line trenches 176. The gate divider rail structures 154 provide lateral electrical and physical isolation of the gate conductor rails 140 along the second horizontal direction hd2. Thus, the gate divider rail structures 154 are formed through the gate conductor material layer 140L as formed at the processing steps of FIGS. 3A and 3B. The gate divider rail structures 154 laterally extend along the first horizontal direction hd1 and are laterally spaced among one another along the second horizontal direction hd2. Vertical cross-sectional shapes of the gate divider rail structures 154 can be flared at an upper end. If the topmost surfaces of the disposable spacers 164 are recessed relative to the top surfaces of the hard mask strips 172, the width of the flared portion of each gate divider rail structure 154 can be the width of a first line trench, which is the pitch of the gate divider rail structures 154 along the second horizontal direction less the width of a hard mask strip 172 along the second horizontal direction hd2.

Referring to FIGS. 8A and 8B, the hard mask strips 172 can be removed selective to the gate divider rail structures 154 and the sacrificial material strips 162. For example, if the hard mask strips 172 include silicon nitride, a wet etch process employing hot phosphoric acid can be employed to remove the hard mask strips 172 selective to the gate divider rail structures 154 and the sacrificial material strips 162.

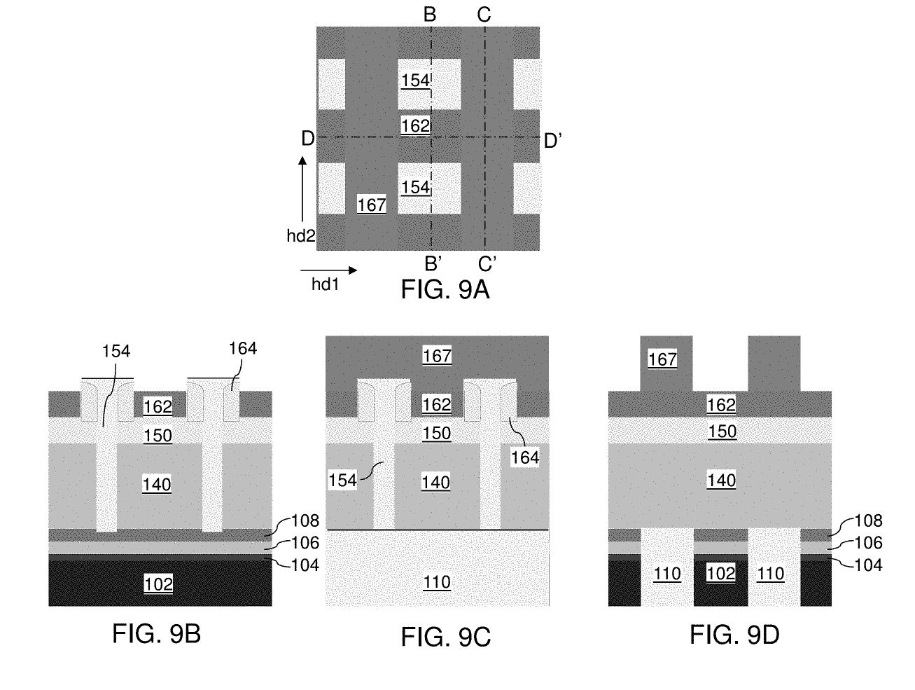

Referring to FIGS. 9A-9D, a second photoresist layer 167 and an optional hard mask (e.g., a carbon hard mask, such as Advanced Patterning Film from Applied Materials) can be applied over the first exemplary structure, and can be lithographically patterned to form a line pattern that is repeated along the first horizontal direction hd1. Each patterned portion of the second photoresist layer 167 laterally extends along the second horizontal direction hd2, and has a uniform width along the first horizontal direction hd1. The pitch of the line pattern along the first horizontal direction can be the same as the pitch of the alternating sequence of the conductive rails 102 and the dielectric separator rails 110 that alternate along the second horizontal direction hd2. The areas of the patterned portions of the second photoresist layer 167 can overlap with the areas of the dielectric separator rails 110, and the areas of the line trenches between the patterned portions of the second photoresist layer 167 can overlap with the areas of the conductive rails 102. Each patterned portion of the second photoresist layer 167 can straddle multiple disposable spacers 164 and multiple gate conductor rails 140. If the optional hard mask is present, then the second photoresist layer 167 can optionally removed at this time to leave the hard mask in place.

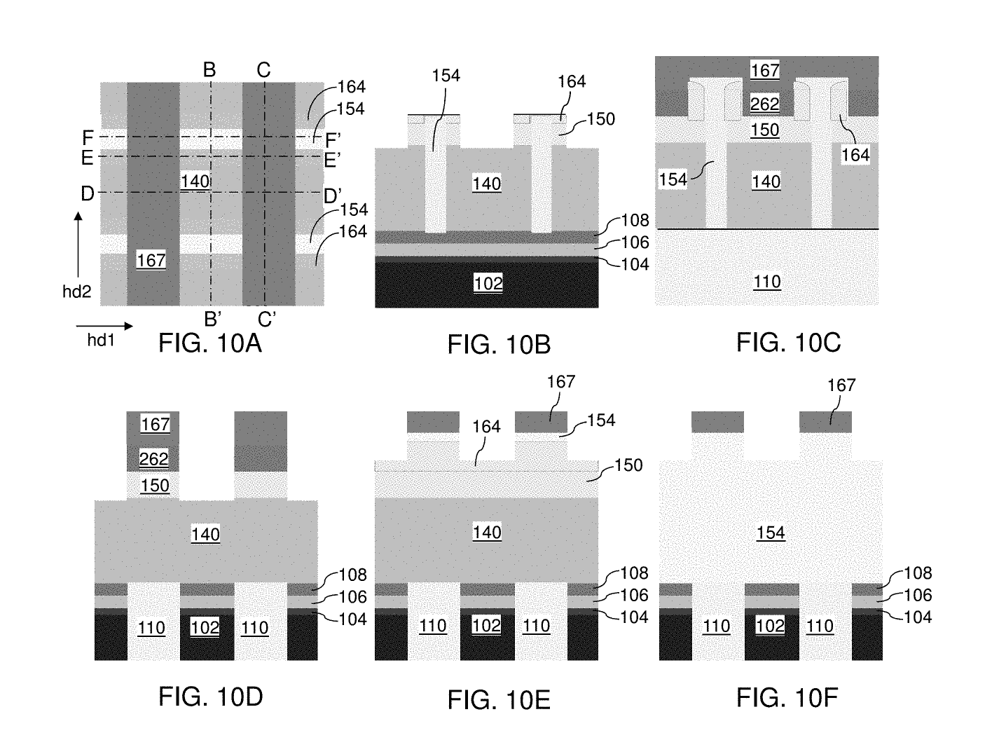

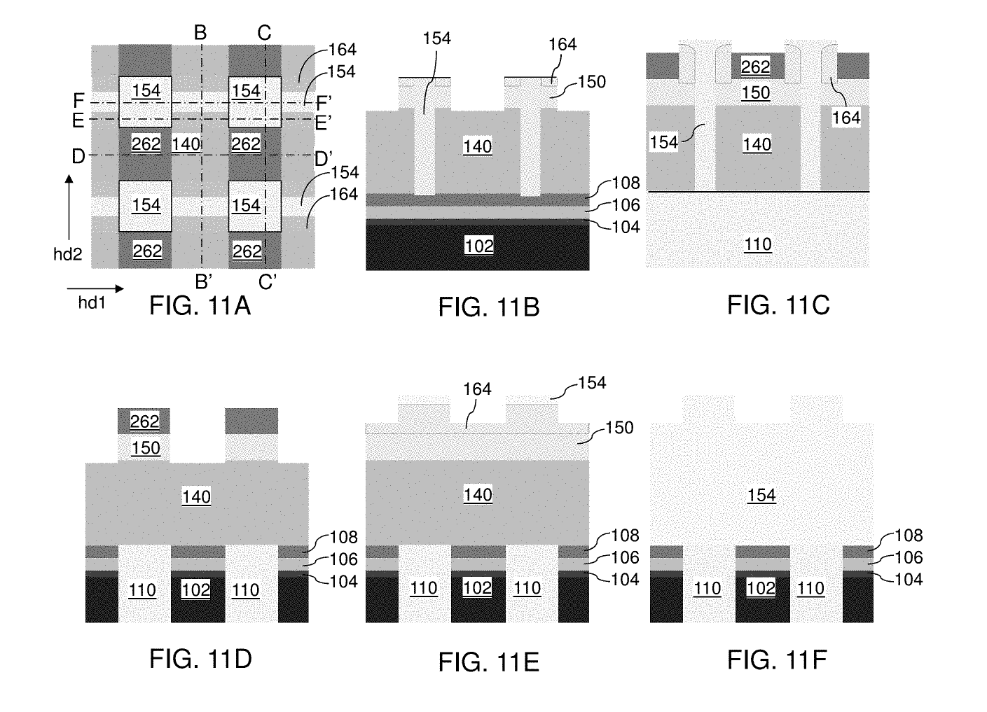

Referring to FIGS. 10A-10F, the pattern in the second photoresist layer 167 (and/or in the optional hard mask) can be transferred through the sacrificial material strips 162 and the dielectric cap structures 150 by a first anisotropic etch process. Portions of the sacrificial material strips 162 that are physically exposed in the second photoresist layer 167 and/or in the optional hard mask, can be removed by the first anisotropic etch, which patterns the sacrificial material strips 162 into sacrificial material portions 262. The dielectric cap structures 150 are patterned to form rectangular openings in areas that are not covered by the second photoresist layer 167 or the disposable spacers 164. Portions of the disposable spacers 164 that are not covered by the second photoresist layer 167 can be vertically recessed.

In one embodiment, the thickness of the sacrificial matrix layer 160 as formed at the processing steps of FIGS. 3A and 3B can be greater than the thickness of the dielectric cap layer 150L as formed at the processing steps of FIGS. 3A and 3B. In this case, the disposable spacers 164 and the dielectric cap structures 150 can include the same material (such as silicon oxide), and remaining portions of the disposable spacers 164 can protect underlying portions of the dielectric cap structures 150. Each dielectric cap structure 150 can include a pair of rail portions that underlie a respective one of the disposable spacers 164 and laterally extend along the first horizontal direction, and rung portions that underlie a respective one of patterned portions of the second photoresist layer 167 and laterally extend along the second horizontal direction between the pair of rail portions. The rectangular openings in each dielectric cap structure 150 are formed between the pair of rail portions and a neighboring pair of rung portions of the dielectric cap structure 150. The fluted upper portions of the gate divider dielectric structures 154 can be removed in areas that are not covered by the second photoresist layer 167.

Referring to FIGS. 11A-11F, the second photoresist layer 167 (if still present) can be removed, for example, by ashing. If the optional hard mask is present, then it can be removed by ashing or selective etching.

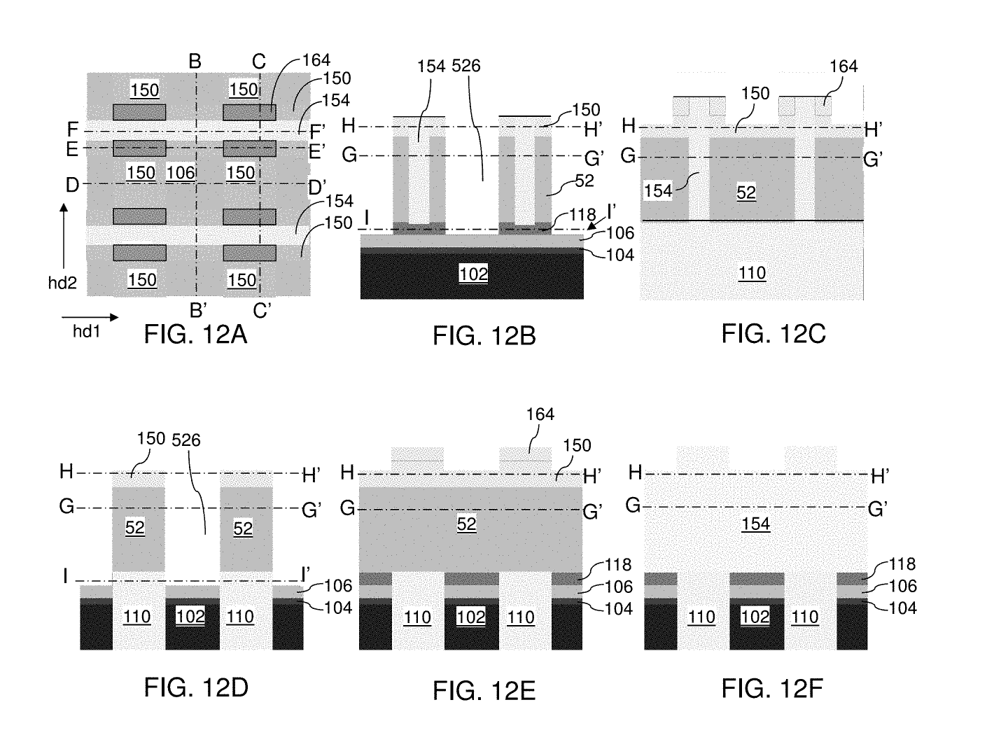

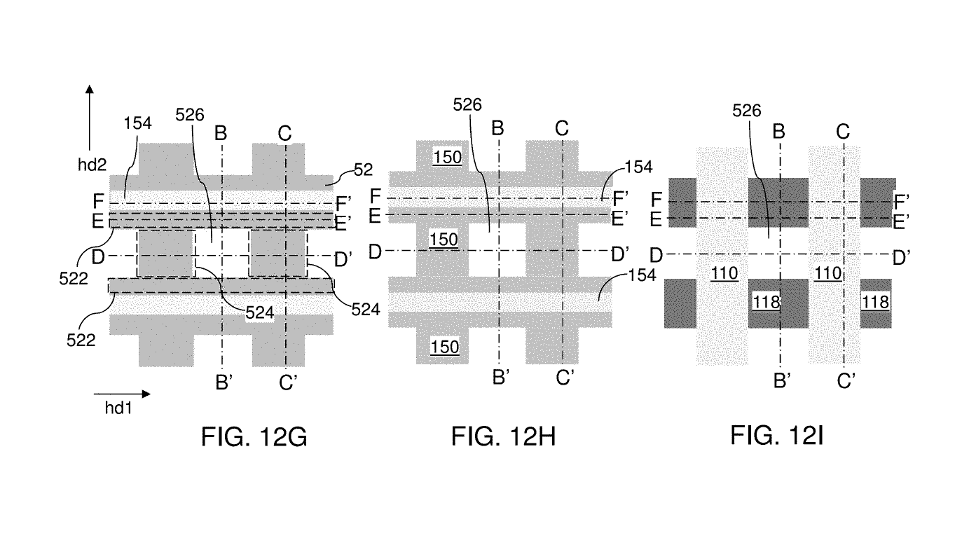

Referring to FIGS. 12A-12I, a second anisotropic etch is performed to etch unmasked portions of the gate conductor rails 140 and the planar insulating strips 108. The combination of the disposable spacers 164 and the dielectric cap structures 150 is employed as an etch mask for the second anisotropic etch. The chemistry of the anisotropic etch can be selected to etch the material of the gate conductor rails 140 selective to the material of the dielectric cap structures 150 and the gate divider rail structures 154. The disposable spacers 164 may be collaterally partially etched. Because the areas of the disposable spacers 164 are entirety within the areas of the dielectric cap structures 150, the pattern that is transferred through the gate conductor rails 140 can be the pattern of openings in the dielectric cap structures 150.

In one embodiment, the sacrificial material portions 262 can be collaterally removed from above the dielectric cap structures 150 during the second anisotropic etch. In one embodiment, the gate conductor rails 140 can include a doped semiconductor material (such as doped polysilicon) and the sacrificial material portions 262 can include a semiconductor material (which may be doped or undoped). In this case, the sacrificial material portions 262 can be completely removed during the second anisotropic etch.

Portions of the gate conductor rails 140 are removed from outside the combination of the areas of the disposable spacers 164 as formed at the processing steps of FIGS. 5A and 5B and the areas of the patterned portions of the second photoresist layer 167 as patterned at the processing steps of FIGS. 10A-10F. The transfer of the pattern of the dielectric cap structures 150 through the gate conductor rails 140 patterns the gate conductor rails 140 into gate electrode lines 52, each of which has a respective ladder shape, as shown in FIG. 12G. Rectangular openings 526 are formed in each of the gate conductor rails 140, as shown in FIG. 12G. Each of the gate electrode lines 52 can be a ladder-shaped gate electrode line including a row of rectangular openings that extend along the first horizontal direction hd1. Thus, remaining portions of the gate conductor rails 140 after formation of the openings therethrough include a one-dimensional array of ladder-shaped gate electrode lines 52 that are repeated along the second horizontal direction. Each of the ladder-shaped gate electrode lines 52 comprises a pair of rail portions 522 that laterally extend along the first horizontal direction hd1 and spaced among one another along the second horizontal direction hd2 and rung portions 524 extending between the pair of rail portions 522 along the second horizontal direction hd2. Each of the pair of rail portions 522 can have the same width as the disposable spacers 164.

The unmasked portions of the planar insulating strips 108 are subsequently etched by the second anisotropic etch. Each planar insulating strip 108 is divided into multiple dielectric material portions, which are herein referred to as insulating spacer plates 118, as shown in FIGS. 12B, 12E, 12F and 12G. Each insulating spacer plate 118 can have a rectangular area, of which the width along the second horizontal direction hd2 is the same as the sum of the width of a bottom portion of a gate divider rail structure 154 and twice the width of the disposable spacers 164 (which is the same as twice the width of a rail portion 522 of a ladder-shaped gate electrode line 52). The width of each insulating spacer plate 118 along the first horizontal direction is the same as that of the underlying conductive rails 102.

A two-dimensional array of insulating spacer plates 118 is provided. The insulating spacer plates 118 contact the rail portions 522 of the one-dimensional array of ladder-shaped gate electrode lines 52 and does not contact the rung portions 524 of the one-dimensional array of ladder-shaped gate electrode lines 52 which are located over the dielectric separator rails. A top surface of a doped semiconductor strip 106 (e.g., the top of the global source or drain region) is physically exposed from each area from which a portion of the planar insulating strip 108 is removed.

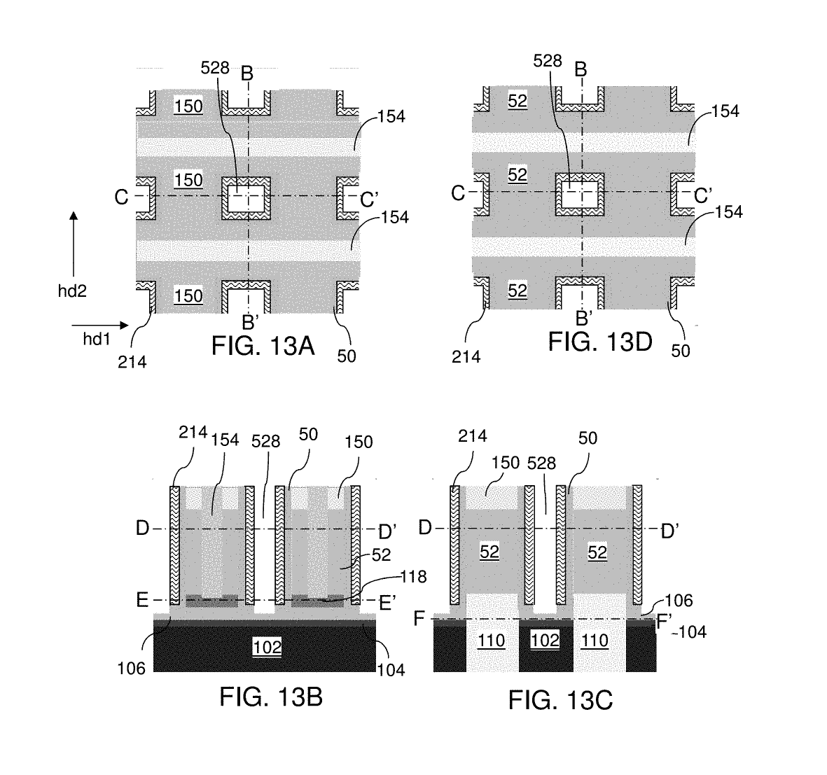

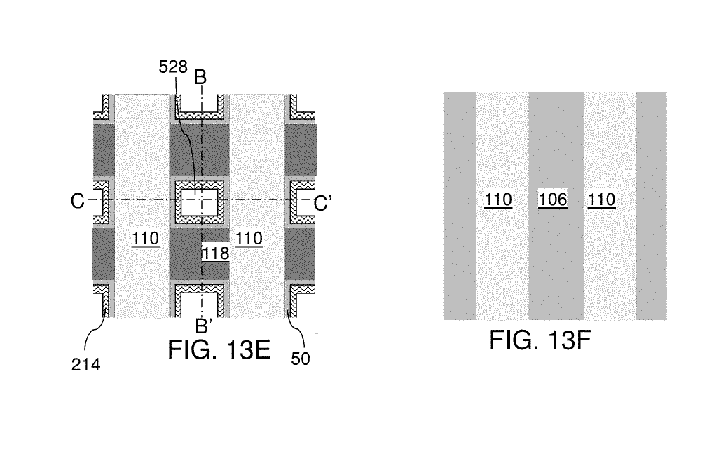

Referring to FIGS. 13A-13F, gate dielectrics 50 and first vertical channel portions 214 can be formed on the first exemplary structure. For example, a continuous gate dielectric layer including at least one dielectric material (such as silicon oxide, silicon oxynitride, a dielectric metal oxide, or a combination thereof) can be formed by a conformal deposition on the sidewalls of the gate electrode lines 52, on a subset of sidewalls of the insulating spacer plates 118, on physically exposed top surfaces of the doped semiconductor strips 106 in the rectangular openings 526, on top surfaces of the gate divider rail structures 154, and on the top surfaces and physically exposed sidewalls of the dielectric cap structures 150. In case the material of the gate electrode lines 52 includes a semiconductor material (such as doped polysilicon), at least a portion of the gate dielectrics 50 can be formed by converting surface portions of the gate electrode lines 52 into dielectric material portions by an oxidation process (which may include thermal oxidation or plasma oxidation) and/or a nitridation process (which may include thermal nitridation or plasma nitridation) in lieu of, or in addition to, formation of the continuous gate dielectric layer.

A doped semiconductor material of a second conductivity type that is the opposite of the first conductivity type can be conformally deposited on the continuous gate dielectric layer (for example, by low pressure chemical vapor deposition) to form a conformal doped semiconductor material layer. For example, if the first conductivity type (which is the conductivity type of the doped semiconductor material of the doped semiconductor strips 106) is n-type, the second conductivity type is p-type, and vice versa. The thickness of the conformal doped semiconductor material layer can be in a range from 5 nm to 100 nm, although lesser and greater thicknesses can also be employed.

An anisotropic etch is performed to remove horizontal portions of the conformal doped semiconductor material layer and horizontal portions of the continuous gate dielectric layer. Each remaining vertical portion of the conformal doped semiconductor material layer constitutes a first vertical channel portion 214, which can have a hollow rectangular configuration with a rectangular outer periphery and a rectangular inner periphery. Each remaining portion of the continuous gate dielectric layer (or any discrete equivalents thereof that are formed by conversion of surface portions of the gate electrode lines 52) constitutes a gate dielectric 50. In one embodiment, each gate dielectric 50 has a hollow configuration within a rectangular outer periphery and a rectangular inner periphery. Each first vertical channel portion 214 can be nested inside a respective gate dielectric 50. In one embodiment, the gate dielectrics 50 can have a horizontal “foot” portion that underlies a first vertical channel portion 214. The gate dielectrics 50 are formed on the sidewalls of the rectangular openings 526 within the gate electrode lines 52.

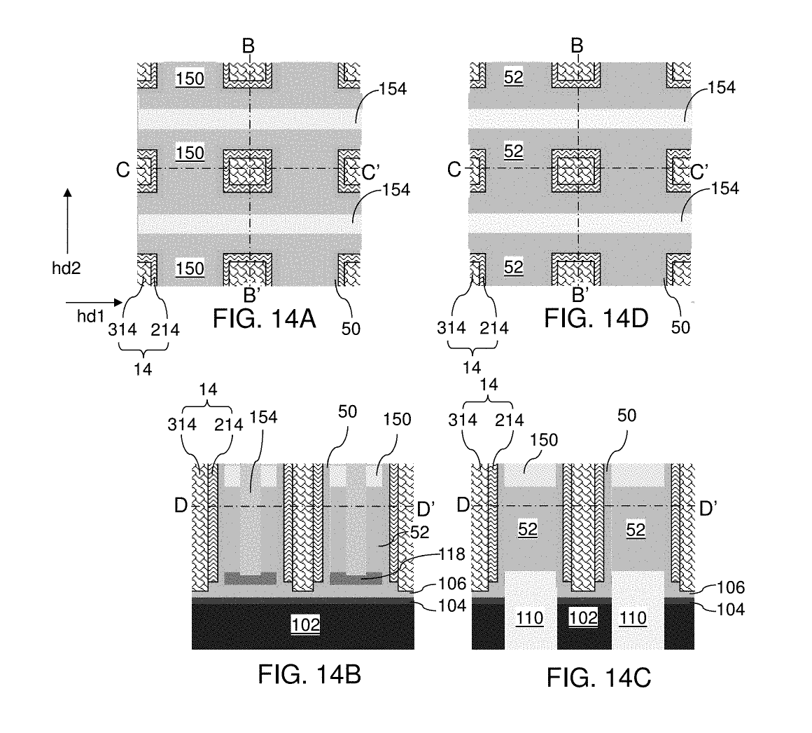

Referring to FIGS. 14A-14D, a doped semiconductor material of the second conductivity type can be deposited in the cavities 528 within the first vertical channel portions 214 by a conformal deposition process such as low pressure chemical vapor deposition. The cavities 528 within the first vertical channel portions 214 can be filled with the doped semiconductor material. Excess portions of the deposited doped semiconductor material and any protruding portion of the exemplary structure (such as the remaining portions of the disposable spacers 164 or protruding portions of the dielectric cap structures 150 as illustrated in FIGS. 12C and 12E) that protrude above the top surfaces of the dielectric cap structures 150 overlying the rung portions 524 of the gate electrode lines 52 can be removed by a planarization process such as chemical mechanical planarization (CMP). Each remaining portion of the deposited doped semiconductor material constitutes a second vertical channel portion 314, which can have a shape of a rectangular pillar.

Each adjoining pair of a first vertical channel portion 214 and a second vertical channel portion 314 constitutes a vertical semiconductor channel 14. Thus, a vertical semiconductor channel 14 is formed within each of the gate dielectrics 50 by deposition of at least one semiconductor material having a doping of the second conductivity type that is different from the first conductivity type.

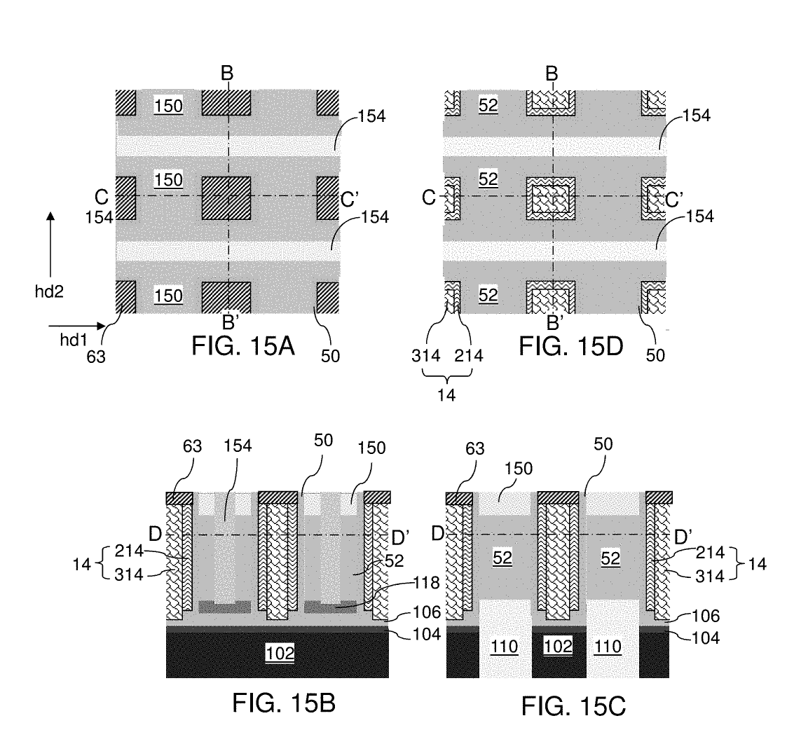

Referring to FIGS. 15A-15D, dopants of the first conductivity type can be implanted into upper portions of the vertical semiconductor channels 14 by ion implantation or plasma doping. Top active regions 63 (which may be source regions or drain regions depending on the operational mode of the vertical field effect transistors to be formed) having a doping of the first conductivity type can be formed by conversion of a top portion of each vertical semiconductor channel 14. A remaining portion of a vertical semiconductor channel 14 contacts a bottom surface of each top active region 63. The energy and dose of the ion implantation can be selected such that the top active regions 63 grows in size during a subsequent anneal process so as to provide an optimal overlap with the gate electrodes as embodied as the gate electrode lines 52.

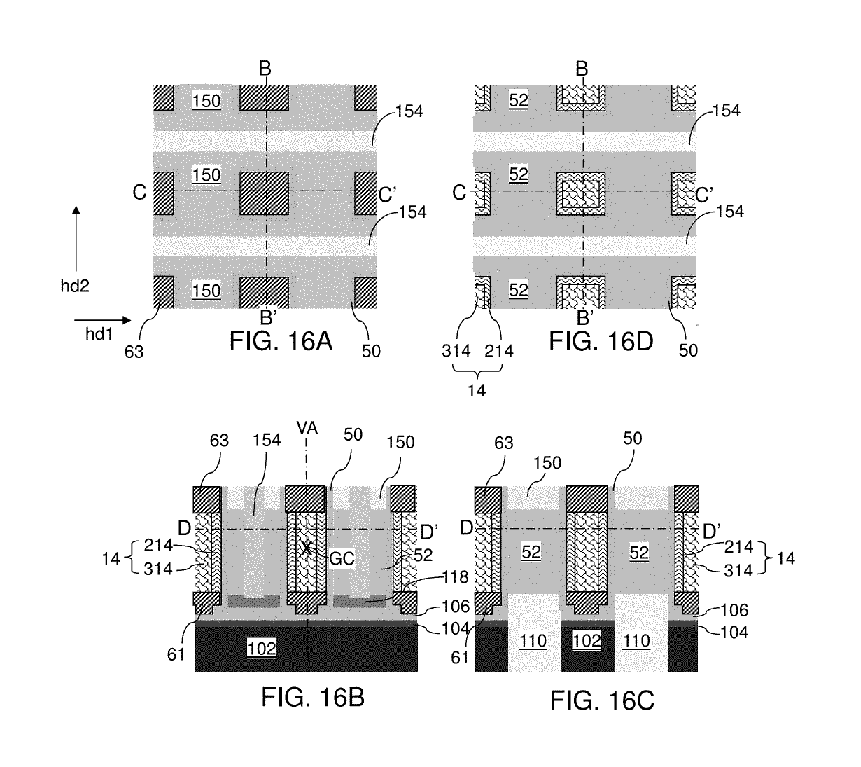

Referring to FIGS. 16A-16D, an anneal process is performed at an elevated temperature to induce outdiffusion of dopants of the first conductivity type from the doped semiconductor strips 106 (which is derived from the doped semiconductor material layer 106L as formed at the processing steps of FIGS. 1A and 1B) into lower portions of the vertical semiconductor channels 14. A bottom portion of each vertical semiconductor channel 14 is converted into a bottom active region 61, which can be a local source region or a local drain region of a select transistor depending on the operational mode of the vertical field effect transistors. For example, if the top active regions 63 are employed as source regions, the bottom active regions 61 can be employed as drain regions, and vice versa. Dopants of the first conductivity type in the top active regions 63 outdiffuse into proximal portions of the vertical semiconductor channels 14 so that the top active regions 63 grow in size. The temperature and the duration of the anneal process can be selected to optimize the vertical overlap between the gate electrode lines 52 and each of the top active regions 63 and the bottom active regions 61.

A two-dimensional array of vertical field effect transistors that are controlled by a one-dimensional array of ladder-shaped gate electrode lines 52 is provided. Each of the ladder-shaped gate electrode lines 52 laterally extends along the first horizontal direction hd1. The bottom active regions 61 of the vertical field effect transistors (e.g., vertical thin film transistors which are the select transistors of an overlying ReRAM device to be formed subsequently) are electrically connected to a respective one of the conductive rails 102 that extend along the second horizontal direction hd2. Each field effect transistor includes a vertical semiconductor channel 14 having a rectangular pillar shape. Each vertical semiconductor channel 14 is laterally surrounded by a respective gate dielectric 50 at all azimuthal angles (i.e., from 0 degrees to 360 degrees) around a vertical axis VA that passes through a geometrical center GC of the vertical semiconductor channel 14, as shown in FIG. 16B. Further, the gate electrode line 52 for each vertical semiconductor channel 14 laterally surrounds the vertical semiconductor channel at all azimuthal angles around the vertical axis VA that passes through the geometrical center GC of the vertical semiconductor channel 14. Thus, each vertical field effect transistor has a surround (i.e., surrounding) gate that controls the current flow through the vertical semiconductor channel 14 with high controllability.

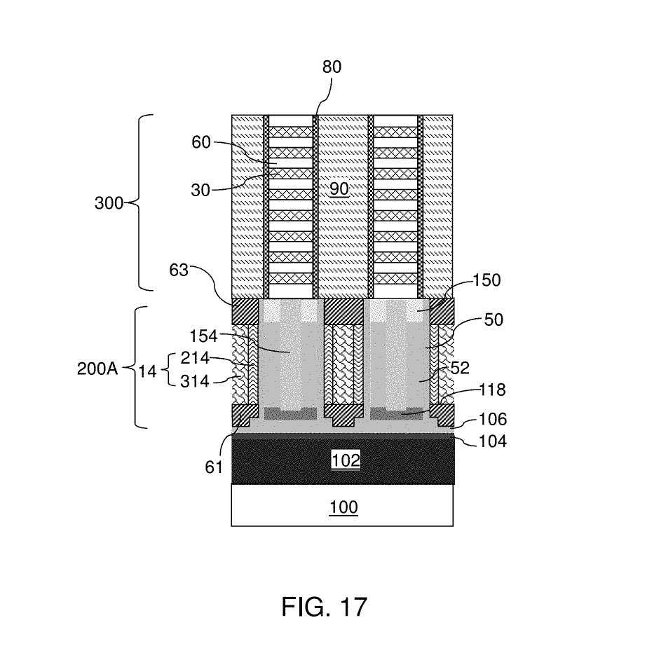

Referring to FIG. 17, a three-dimensional array of memory elements can be formed over the two-dimensional array of vertical field effect transistors. The three-dimensional array of memory elements can be any type of three-dimensional device that can be accessed by a two-dimensional array of vertically extending lines that are electrically shorted to a respective one of the top active regions 63 of the two-dimensional array of vertical field effect transistors.

The first exemplary structure can be formed on a substrate 100 including an insulating top surface. After formation of the first exemplary structure, a plurality of alternating stacks (30, 60) of insulating strips 60 and electrically conductive strips 30 can be formed over the two-dimensional array of vertical field effect transistors. Each layer within an alternating stack (30, 60), i.e., each of the insulating strips 60 and the electrically conductive strips 30 in the alternating stack (30, 60), can laterally extend along a horizontal direction, which may be selected from the first horizontal direction hd1 and the second horizontal direction hd2. Each neighboring pair of alternating stacks (30, 60) can be laterally spaced from each other by a line trench. The line trenches can form a one-dimensional array that is repeated along a horizontal direction that is perpendicular to the horizontal direction along which the layers within each alternating stack (30, 60) laterally extend. The line trenches can be filled with a two-dimensional array of dielectric pillar structures that defines a two-dimensional array of pillar cavities (i.e., cavities having a respective pillar shape). Each pillar cavity is laterally bounded by a neighboring pair of alternating stacks (30, 60) along one horizontal direction, and is laterally bounded by a neighboring pair of dielectric pillar structures along another horizontal direction.

Resistive memory elements 80 can be formed on the sidewalls of the pillar cavities, i.e., on the sidewalls of the plurality of alternating stacks (30, 60). The resistive memory elements 80 may be embodied as a continuous film of a memory material, or may be embodied as discrete memory material portions. As used herein, a “resistive memory material” or a “reversibly resistance-switching material” is a material whose resistivity can be altered by application of an electrical bias voltage across the material. As used herein, a “resistive memory material film” refers to one or ore layers including a resistive memory material. As used herein, a “resistive memory element” refers to a portion of a resistive memory material.

The resistive memory material may be selected from: (i) a non-filamentary barrier modulated cell (BMC) which includes a barrier and an electrically conductive metal oxide whose resistivity is switched by at least one of oxygen ion and/or oxygen vacancy diffusion in response to an application of an electric field thereto; (ii) a phase change material portion providing at least two different levels of resistivity that depend on crystallinity; or (iii) a filamentary metal oxide portion (e.g., hafnium oxide layer) providing at least two different levels of resistivity depending on concentration of conductive filaments therein. Each BMC can include a metal oxide material having at least two resistive states having different resistivity. Examples of metal oxide materials include a slightly sub-stoichiometric metal oxide such as TiO_{2-δ}, SrTiO_{3-δ}, NbO_{2-δ}, or Nb:SrTiO_{3-δ} where value of δ can be independently selected from a range from 0 to 0.5, such as greater than zero to 0.15 (i.e., to form a sub-stoichiometric, oxygen deficient metal oxide). For example, the metal oxide material may be titanium oxide, such as sub-stoichiometric titanium oxide having less than two oxygen atoms for each titanium atom. In one embodiment, the metal oxide may have a high concentration of free electrons in thermodynamic equilibrium in a range from 1.0×10²⁰/cm³ to 1.0×10²¹/cm³. The memory cell may also include a barrier material, such as amorphous silicon or other suitable barrier materials. An interfacial barrier oxide is located between the metal oxide material and the barrier material. For an amorphous silicon barrier material, the interfacial barrier oxide may comprise silicon oxide. Without wishing to be bound by a particular theory, it is believed that the BMC ReRAM device operates as follows. The switching mechanism in BMC stack is generally understood as oxygen interstitial (Oi) generation in the interfacial barrier oxide (e.g., SiO₂) at the amorphous silicon (a-Si)/TiO_{2-δ} interface after a RESET operation (i.e., resetting the stack into the high resistivity state, HRS). The oxygen interstitials may drift into defect rich TiO_{2-δ} where they cause a re-oxidation of the TiO_{2-δ} (e.g., recombine with oxygen vacancies in the TiO_{2-δ} near the interface. This re-oxidation decreases the conductivity of the TiO_{2-δ} material and/or increases the thickness of the insulating interfacial barrier oxide and hence increases the resistance of the BMC memory cell. During the SET operation, opposite voltage is applied across the cell, and Ti—O bonds are supposed to be broken down to generate Oi and Vo (oxygen vacancy) pair in the titanium oxide layer. Oi may drift back to the a-Si/TiO_{2-δ} interface along the electric field to increase the conductivity of the TiO_{2-δ} layer and/or decrease the thickness of the insulating interfacial barrier oxide and hence decrease the resistance of the BMC memory cell to set the memory cell into the low resistivity state, LRS. Without wishing to be bound by a particular theory, it is believed that a BMC ReRAM device may operate based on the principle described above and/or based on an alternative principle instead of or in addition to the principle described above. For example, the BMC ReRAM device may operate by modulation of energy band structure within the cell. When the charge carrier density is modulated, the resistance of the cell is changed. In other words, the resistance of the memory cell may be modulated by changes in the band structure and consequent changes in the charge distribution instead of or in addition to the change in thickness of the interfacial barrier oxide.

Optionally, the resistive memory element 80 may also include an optional steering element, such as a diode, that provides a non-linear current-voltage characteristic for electrical current passing therethrough. In one embodiment, the steering element may have an asymmetric current-voltage characteristic (e.g., a diode which conducts current primarily in one direction (asymmetric conductance)and which has a lower resistance to the flow of current in one direction, and a higher resistance in the other direction).

Vertical bit lines 90 can be formed in remaining volumes of the pillar cavities. Each vertical bit line 90 can be an electrically conductive material pillar which electrically contacts a respective one of the top active regions 63, and can be formed between a respective neighboring pair of alternating stacks (30, 60) among the plurality of alternating stacks (30, 60). In one embodiment, the structure formed above the two-dimensional array of vertical field effect transistors (i.e., the vertical thin film select transistors) 200A can include a three-dimensional array of resistive random access memory (ReRAM) devices 300.

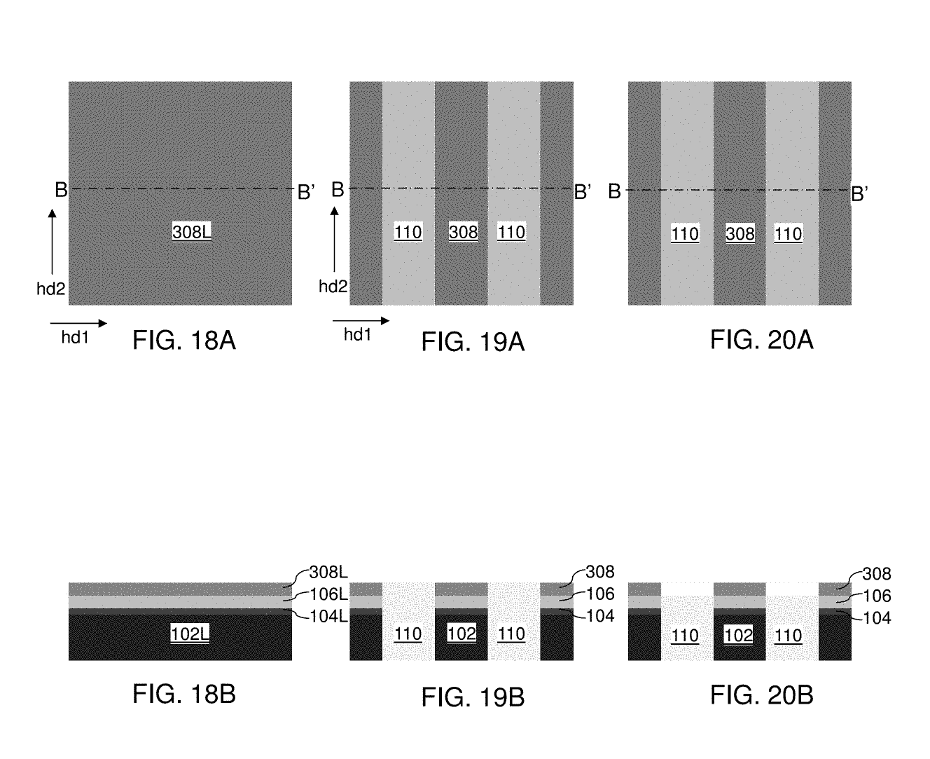

Referring to FIGS. 18A and 18B, a second exemplary structure is illustrated after formation of a layer stack (102L, 104L, 106L, 308L) including a conductive material layer 102L, a metal nitride layer 104L, a doped semiconductor layer 106L, and a sacrificial pad layer 308L. Each of the conductive material layer 102L, the metal nitride layer 104L, and the doped semiconductor layer 106L can be the same as in the first exemplary structure illustrated in FIGS. 1A and 1B. The sacrificial pad layer 308L can include a sacrificial material that can be employed as a stopping layer during a planarization process. For example, the sacrificial pad layer 308L can include a silicon nitride layer having a thickness in a range from 10 nm to 40 nm, although lesser and greater thicknesses can also be employed.

Referring to FIGS. 19A and 19B, line trenches are formed through the layer stack (102L, 104L, 106L, 308L), for example, by applying and patterning a photoresist layer (not shown) over the layer stack (102L, 104L, 106L, 308L) and transferring the pattern in the photoresist layer through the (102L, 104L, 106L, 308L) by at least one anisotropic etch process. The processing steps of FIGS. 2A and 2B can be performed with the substitution of the sacrificial pad layer 308L for the planar insulating spacer layer 108L. An alternating sequence of conductive rails 102 and dielectric separator rails 110 that alternate along the second horizontal direction hd2 is formed. Each remaining portion of the metal nitride layer 104L constitutes a metal nitride strip 104 that laterally extends along the second horizontal direction hd2 and has a uniform width along the first horizontal direction hd1. Each combination of a conductive rail 102 and optional overlying metal nitride strip 104 can correspond to a global bit line of a ReRAM device. The alternating sequence of conductive rails 102 and dielectric separator rails 110 can have a pitch in a range from 50 nm to 400 nm along the first horizontal direction hd1, although lesser and greater pitches can also be employed. The width of the conductive rails 102 can be in a range from 20% to 80% of the pitch. The width of the dielectric separator rails 110 can be in a range from 20% to 80% of the pitch.

Each remaining portion of the doped semiconductor layer 106L constitutes a doped semiconductor strip 106, which is a doped semiconductor layer having a finite width. Specifically, each doped semiconductor strip 106 laterally extends along the second horizontal direction hd2 and has the uniform width along the first horizontal direction hd1. Each remaining portion of the sacrificial pad layer 308L constitutes a sacrificial pad strip 308 that laterally extends along the second horizontal direction hd2 and has the uniform width along the first horizontal direction hd1.

Referring to FIGS. 20A and 20B, the top surfaces of the dielectric separator rails 110 can be vertically recessed by a recess distance that is approximately the same as the thickness of the sacrificial pad strips 308. An isotropic etch process or an anisotropic etch process can be employed. For example, if the dielectric separator rails 110 include silicon oxide, a wet etch process employing hydrofluoric acid can be employed to vertically recess the top surfaces of the dielectric separator rails 110.

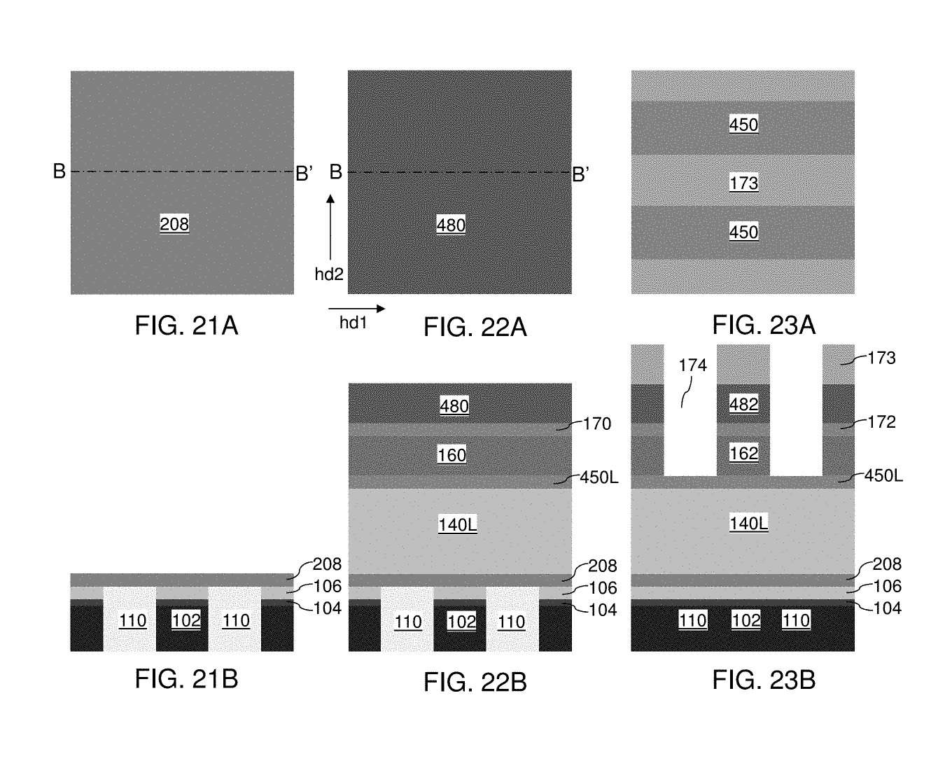

Referring to FIGS. 21A and 22B, the sacrificial pad strips 308 can be removed selective to the doped semiconductor strips 106 and the dielectric separator rails 110. For example, if the sacrificial pad strips 308 include silicon nitride, then a wet etch process employing hot phosphoric acid can be employed to remove the sacrificial pad strips 308.

A planar insulating spacer layer 208 can be subsequently formed on the top surfaces of the doped semiconductor strips 106 and the dielectric separator rails 110. The planar insulating spacer layer 208 includes a dielectric material and has a uniform thickness. For example, the planar insulating spacer layer 208 can include silicon oxide, silicon oxynitride, or silicon nitride, and can have a thickness in a range from 4 nm to 40 nm, although lesser and greater thicknesses can also be employed.

Referring to FIGS. 22A and 22B, a gate conductor material layer 140L, a dielectric cap layer 450L, a sacrificial matrix layer 160, a first hard mask layer 170, and a second hard mask layer 480 can be sequentially formed. The gate conductor material layer 140L includes a conductive material that is subsequently patterned into gate electrode lines. The gate conductor material layer 140L can include a doped semiconductor material (such as doped polysilicon or an amorphous doped polysilicon that can be subsequently annealed into doped polysilicon) or a metallic material (such as a conductive metal nitride, an elemental metal, or an intermetallic alloy). For example, the gate conductor material layer 140L can include doped polysilicon. The thickness of the gate conductor material layer 140L can be in a range from 100 nm to 500 nm, such as from 150 nm to 250 nm, although lesser and greater thicknesses can also be employed.

The dielectric cap layer 450L includes a dielectric material that subsequently provides vertical electrical insulation between the gate electrode lines to be formed and structures to be formed thereabove. For example, the dielectric cap layer 450L can include silicon nitride. The thickness of the dielectric cap layer 150L can be in a range from 15 nm to 60 nm, such as from 20 nm to 45 nm, although lesser and greater thicknesses can also be employed.

The sacrificial matrix layer 160 includes a sacrificial material (a material that is subsequently removed) that functions as a matrix for forming self-aligned spacers in subsequent processing steps. The sacrificial matrix layer 160 can include a material that can be removed selective to the material of the dielectric cap layer 150L. For example, the sacrificial matrix layer 160 can include silicon or a silicon-germanium alloy, which may, or may not, be doped with electrical dopants, and may be amorphous or polycrystalline. In one embodiment, the sacrificial matrix layer 160 can include undoped amorphous silicon. The thickness of the sacrificial matrix layer 160 can be in a range from 50 nm to 200 nm, such as from 75 nm to 150 nm, although lesser and greater thicknesses can also be employed.

The first hard mask layer 170 includes a hard mask material that can be subsequently employed as a planarization stopping layer during a chemical mechanical planarization process. For example, the first hard mask layer 170 can include silicon nitride. The thickness of the first hard mask layer 170 can be in a range from 20 nm to 50 nm, although lesser and greater thicknesses can also be employed.

The second hard mask layer 480 includes a hard mask material that is different from the material of the first hard mask layer 170. For example, the second hard mask layer 480 can include silicon oxide (e.g., dTEOS type oxide comprising densified silicon oxide from a TEOS source. The thickness of the second hard mask layer 480 can be in a range from 50 nm to 200 nm, such as from 75 nm to 150 nm, although lesser and greater thicknesses can also be employed.

Referring to FIGS. 23A and 23B, a first photoresist layer 173 is applied over the second hard mask layer 480, and is lithographically patterned with a line pattern. Line trenches laterally extending along a direction that is perpendicular to the lengthwise directions of the conductive rails 102 and the dielectric separator rails 110 are formed. For example, the line trenches in the patterned first photoresist layer 173 can laterally extend along the first horizontal direction hd1, and can be laterally spaced among one another along the second horizontal direction hd2. The patterned first photoresist layer 173 can have a pitch in a range from 50 nm to 400 nm along the second horizontal direction hd2, although lesser and greater pitches can also be employed.

An anisotropic etch is performed to transfer the pattern of the first photoresist layer 173 through the second hard mask layer 480, the first hard mask layer 170, and the sacrificial matrix layer 160. The anisotropic etch can stop on the dielectric cap layer 450L. Line trenches 174 are formed through the stack of the sacrificial matrix layer 160, the first hard mask layer 170, and the second hard mask layer 480, which are herein referred to as first line trenches. Each remaining portion of the sacrificial matrix layer 160 is herein referred to as a sacrificial material strip 162. Each remaining portion of the first hard mask layer 170 is herein referred to as first hard mask strips 172. Each remaining portion of the second hard mask layer 480 is herein referred to as second hard mask strips 482. The first line trenches can laterally extend along the first horizontal direction hd1, and can be arranged as a one-dimensional periodic array that is repeated along the second horizontal direction with a pitch, which may be in a range from 50 nm to 400 nm. The width of each first line trench may be in a range from 20% to 80% of the pitch of the first line trenches along the second horizontal direction. The patterned first photoresist layer 173 can be subsequently removed, for example, by ashing.

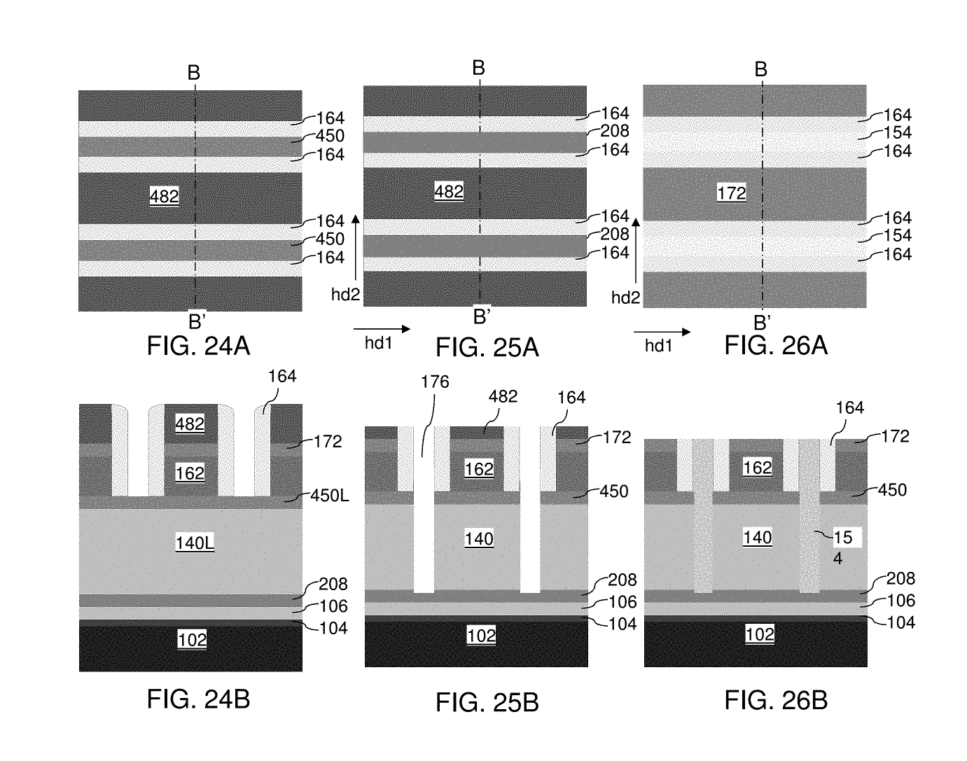

Referring to FIGS. 24A and 24B, disposable spacers 164 can be formed on sidewalls of the first line trenches 174 by depositing and anisotropically etching a conformal disposable material layer. In one embodiment, the disposable spacers 164 can include silicon oxide or an organosilicate glass. The disposable spacers 164 are self-aligned to the sidewalls of the first line trenches, and thus, are self-aligned disposable spacers. As such, pairs of disposable spacers 164 constitute a one-dimensional periodic array along the second horizontal direction hd2 having a same pitch as the pitch of the first line trenches. Each disposable spacer 164 can contact sidewalls of a pair of sacrificial material strips 162 and sidewalls of a pair of first hard mask strips 172, and may optionally contact sidewalls of a pair of second hard mask strips 482. The width of each disposable spacer 164 may be in a range from 5% to 45% of the width of a line trench. A cavity is laterally enclosed by each disposable spacer 164.

Referring to FIGS. 25A and 25B, an anisotropic etch is performed to transfer the pattern of each cavity within the disposable spacers 164 through the dielectric cap layer 450L and the gate conductor material layer 140L. The anisotropic etch process can include a first step that etches the material of the dielectric cap layer 450L selective to the material of the second hard mask strips 482 and optionally selective to the material of the disposable spacers 164, and a second step that etches the material of the gate conductor material layer 140L selective to the materials of the second hard mask strips 482 and the disposable spacers 164. Second line trenches 176 are formed through the gate conductor material layer 140L in areas that are not covered by remaining portions of the first and second hard mask layers (170, 480) (i.e., the first hard mask strips 172 and the second hard mask strips 482) or the disposable spacers 164. The second line trenches 176 laterally extend along the first horizontal direction hd1, and are laterally spaced among one another along the second horizontal direction hd2. Remaining portions of the gate conductor material layer 140L include gate conductor rails 140 that may have a respective uniform width (along the second horizontal direction hd2) throughout, and are laterally separated among one another by the second line trenches 176. Remaining portions of the dielectric cap layer 450L include dielectric cap structures 450 that have the same width as a respective underlying gate conductor rail 140, and are laterally spaced among one another by the second line trenches 176.

Referring to FIGS. 26A and 26B, a dielectric material such as silicon oxide is deposited in the second line trenches 176. The dielectric material can be deposited by a conformal deposition process such as low pressure chemical vapor deposition (LPCVD) or spin-coating. Material portions located above the horizontal plane including the top surfaces of the first hard mask strips 172 and/or the top surfaces of the second hard mask strips 482 can be removed, for example, by chemical mechanical planarization (CMP). The material portions that are removed by the CMP process can include the excess portions of the dielectric material that are deposited above the horizontal plane including the top surfaces of the first hard mask strips 172, the second hard mask strips 482, and upper portions of the disposable spacers 164 located above the horizontal plane including the top surfaces of the first hard mask strips 172. In one embodiment, the deposited dielectric material, the second hard mask strips 482, and the disposable spacers 164 can include silicon oxide, and the first hard mask strips 172 can include silicon nitride. The first hard mask strips 172 can be employed as stopping structures during the CMP process.

The remaining portions of the dielectric material in the second line trenches 176 constitute a dielectric rail structure, which is herein referred to as gate divider rail structures 154. Each gate divider rail structure 154 is formed within the volume of a respective one of the second line trenches 176. The gate divider rail structures 154 provide lateral electrical and physical isolation of the gate conductor rails 140 along the second horizontal direction hd2. Thus, the gate divider rail structures 154 are formed through the gate conductor material layer 140L as formed at the processing steps of FIGS. 22A and 22B. The gate divider rail structures 154 laterally extend along the first horizontal direction hd1 and are laterally spaced among one another along the second horizontal direction hd2. Vertical cross-sectional shapes of the gate divider rail structures 154 can be flared at an upper end. The width of the gate divider rail structures 154 can be substantially uniform irrespective of the height, which is the pitch of the gate divider rail structures 154 along the second horizontal direction less the width of a hard mask strip 172 along the second horizontal direction hd2 less twice the width of a disposable spacer 164.

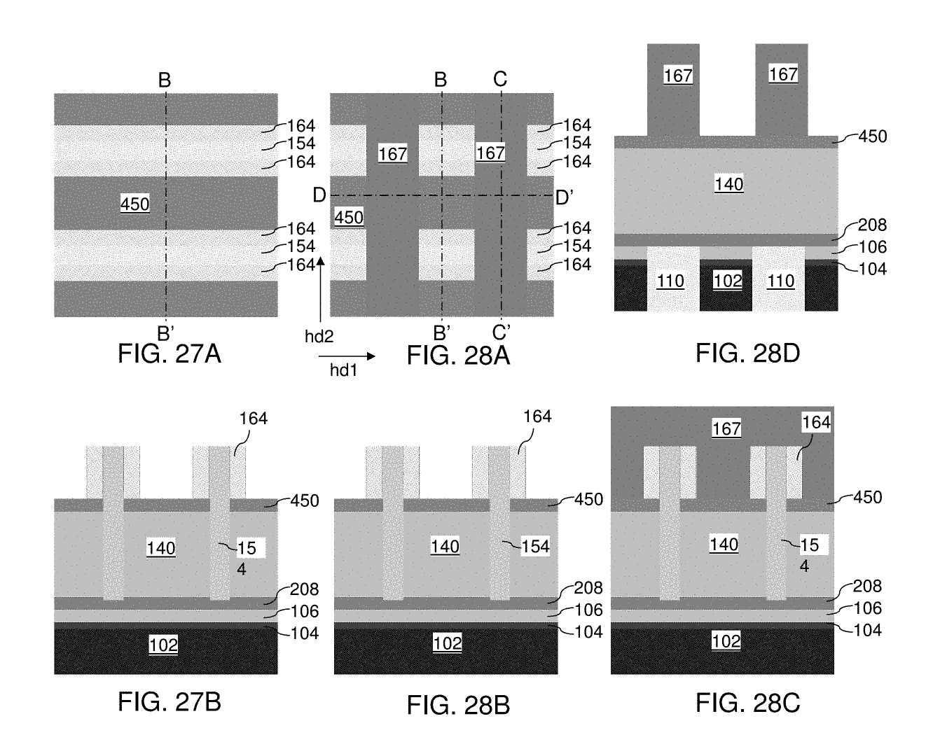

Referring to FIGS. 27A and 27B, the first hard mask strips 172 can be removed selective to the gate divider rail structures 154. For example, if the hard mask strips 172 include silicon nitride, a wet etch process employing hot phosphoric acid can be employed to remove the hard mask strips 172 selective to the gate divider rail structures 154.

Subsequently, the sacrificial material strips 162 can be removed selective to the gate divider rail structures 154 and the dielectric cap structures 450. For example, if the sacrificial material strips 162 include amorphous silicon, the gate divider rail structures 154 include silicon oxide, and the dielectric cap structures 450 include silicon nitride, a wet etch employing a trimethyl-2 hydroxyethyl ammonium hydroxide (TMY) or KOH solution can be employed to remove the sacrificial material strips 162 selective to the gate divider rail structures 154 and the dielectric cap structures 450.

Referring to FIGS. 28A-28D, a second photoresist layer 167 (and optional hard mask) can be applied over the second exemplary structure, and can be lithographically patterned to form a line pattern that is repeated along the first horizontal direction hd1. Each patterned portion of the second photoresist layer 167 laterally extends along the second horizontal direction hd2, and has a uniform width along the first horizontal direction hd1. The pitch of the line pattern along the first horizontal direction can be the same as the pitch of the alternating sequence of the conductive rails 102 and the dielectric separator rails 110 that alternate along the second horizontal direction hd2. The areas of the patterned portions of the second photoresist layer 167 can overlap with the areas of the dielectric separator rails 110, and the areas of the line trenches between the patterned portions of the second photoresist layer 167 can overlap with the areas of the conductive rails 102. Each patterned portion of the second photoresist layer 167 can straddle multiple disposable spacers 164 and multiple gate conductor rails 140.

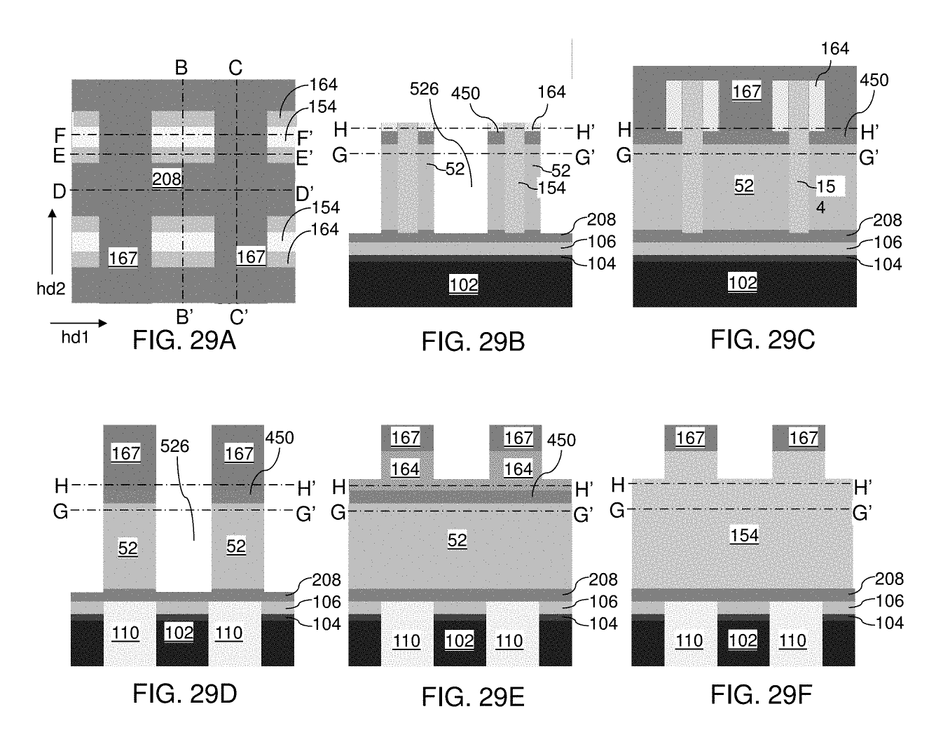

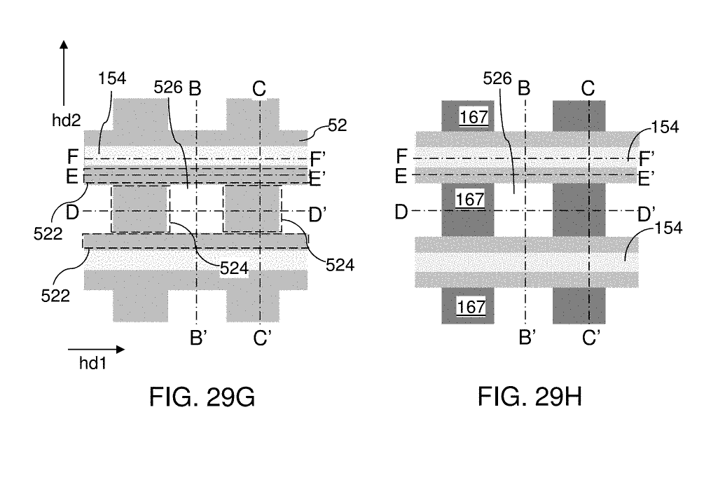

Referring to FIGS. 29A-29H, the pattern in the second photoresist layer 167 can be transferred through the dielectric cap structures 450 and the gate conductor rails 140 by an anisotropic etch process. The anisotropic etch can include a first step that etches the material of the dielectric cap structures 450 and a second step that etches the material of the gate conductor rails 140.

During the first step of the anisotropic etch, the dielectric cap structures 450 are patterned to form rectangular openings 526 in areas that are not covered by the second photoresist layer 167 or the disposable spacers 164. Portions of the disposable spacers 164 that are not covered by the second photoresist layer 167 can be vertically recessed. Each dielectric cap structure 450 can include a pair of rail portions that underlie a respective one of the disposable spacers 164 and laterally extend along the first horizontal direction hd1, and rung portions that underlie a respective one of patterned portions of the second photoresist layer 167 and laterally extend along the second horizontal direction between the pair of rail portions. The rectangular openings 526 in each dielectric cap structure 450 are formed between the pair of rail portions and a neighboring pair of rung portions of the dielectric cap structure 450.

The chemistry of the second step of the anisotropic etch can be selected to etch the material of the gate conductor rails 140 selective to the material of the gate divider rail structures 154. The chemistry of the second step of the anisotropic etch can be selective to at least one of the material of the disposable spacers 164 and the material of the dielectric cap structures 450. The pattern that is transferred through the gate conductor rails 140 can be the pattern of openings in the dielectric cap structures 450.

Portions of the gate conductor rails 140 are removed from outside the combination of the areas of the disposable spacers 164 as formed at the processing steps of FIGS. 24A and 24B and the areas of the patterned portions of the second photoresist layer 167 as patterned at the processing steps of FIGS. 28A-28D. The transfer of the pattern of the dielectric cap structures 450 through the gate conductor rails 140 patterns the gate conductor rails 140 into gate electrode lines 52, each of which has a respective ladder shape. Rectangular openings 526 are formed in each of the gate conductor rails 140. Each gate electrode rail 52 can have the same horizontal cross-sectional shape as the overlying dielectric cap structure 450.

Each of the gate electrode lines 52 can be a ladder-shaped gate electrode line including a row of rectangular openings that extend along the first horizontal direction hd1. Thus, remaining portions of the gate conductor rails 140 after formation of the openings therethrough include a one-dimensional array of ladder-shaped gate electrode lines 52 that are repeated along the second horizontal direction. Each of the ladder-shaped gate electrode lines 52 comprises a pair of rail portions 522 that laterally extend along the first horizontal direction hd1 and spaced among one another along the second horizontal direction hd2 and rung portions 524 extending between the pair of rail portions 522 along the second horizontal direction hd2, as shown in FIG. 29G. Each of the pair of rail portions 522 can have the same width as the disposable spacers 164.

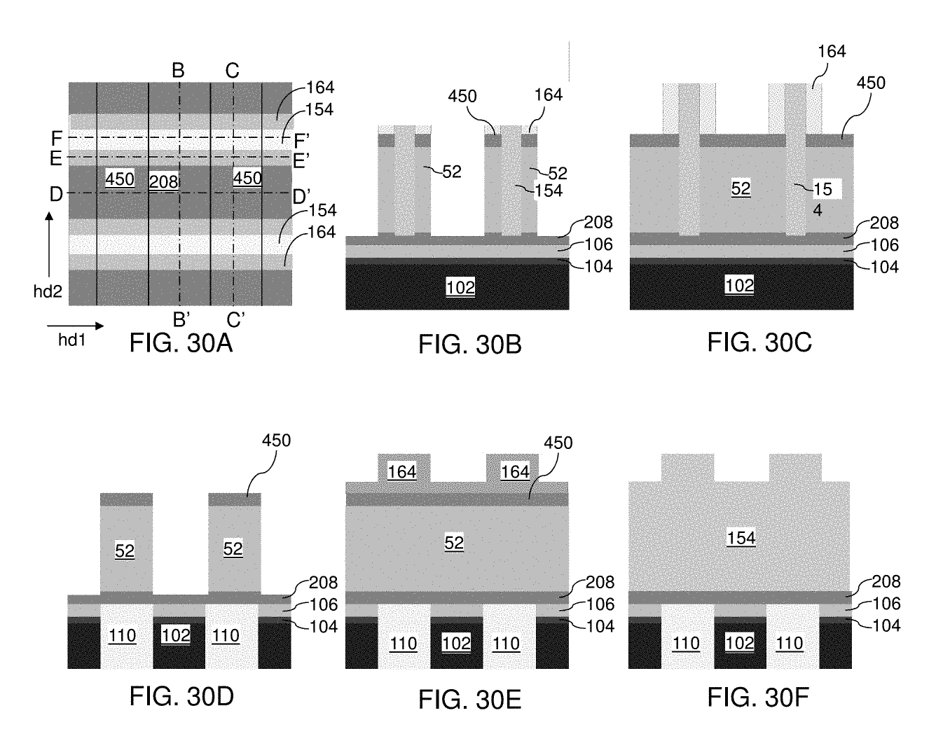

Referring to FIGS. 30A-30F, the second photoresist layer 167 can be removed, for example, by ashing.

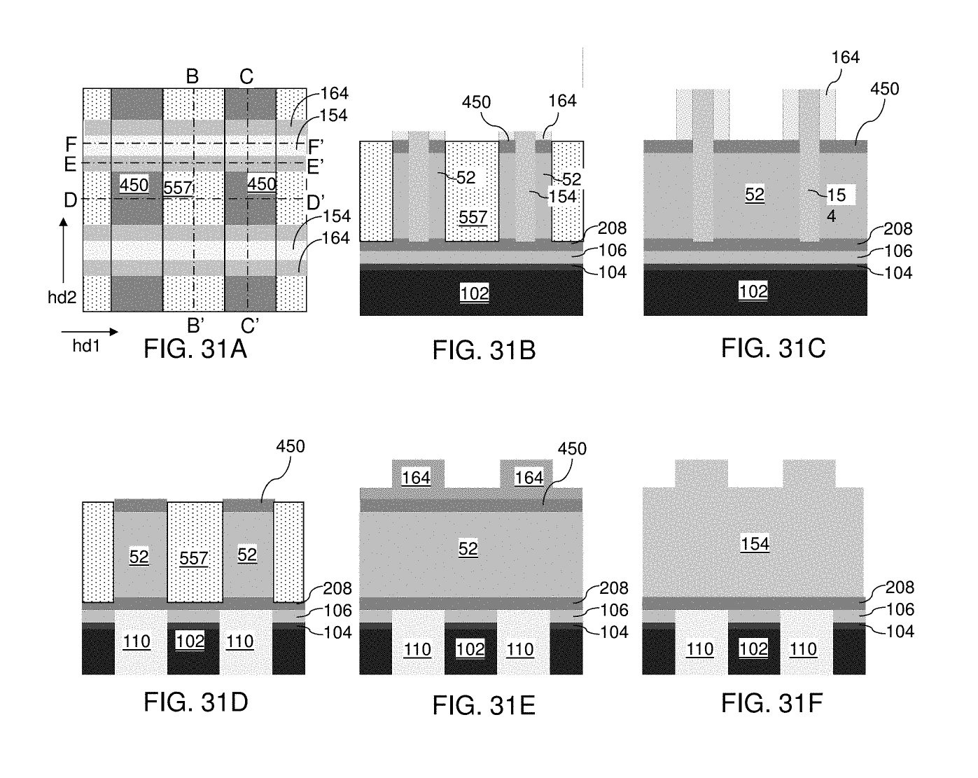

Referring to FIGS. 31A-31F, a sacrificial fill material is deposited in the cavities defined by the openings 526 in the ladder-shaped gate electrode lines 52. The sacrificial fill material is a material that is different from the materials of the dielectric cap structures 450 and the ladder-shaped gate electrode lines 52, and may be different from the materials of the planar insulating spacer layer 208. The sacrificial fill material can be a material that provides mechanical resistance during a subsequent chemical mechanical planarization process. For example, the sacrificial fill material can include amorphous carbon, diamond-like carbon (DLC), organosilicate glass, or a silicon-germanium alloy. Portions of the sacrificial fill material overlying the dielectric cap structures, the gate divider rail structures 154, or the disposable spacers 164 can be removed by a recess etch. Remaining portions of the sacrificial fill material filling the openings 526 in the ladder-shaped gate electrode lines 52 constitute sacrificial pillar structures 557, each of which can have a rectangular horizontal cross-sectional shape. The top surfaces of the sacrificial pillar structures 557 can be located at, above, or below the horizontal plane including the top surfaces of the dielectric cap structures 450.

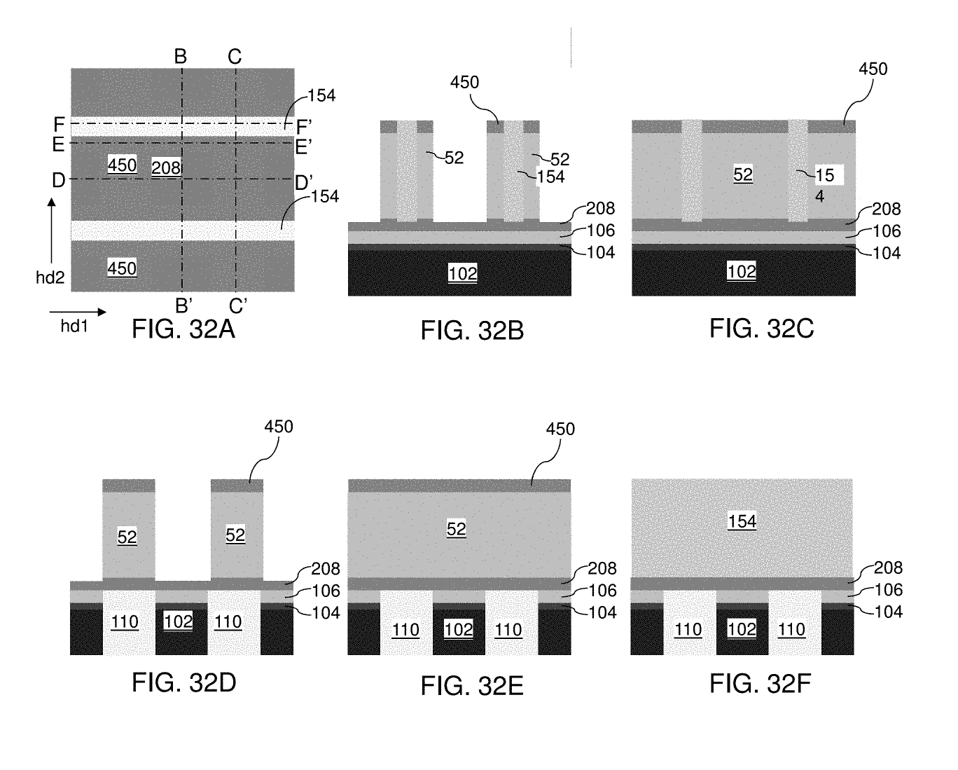

Referring to FIGS. 32A-32F, a chemical mechanical planarization process can be performed to remove material portions that are located above the horizontal plane including the top surfaces of the dielectric cap structures 450. The disposable spacers 164 and the portions of the gate divider rail structures 154 located above the horizontal plane including the top surfaces of the dielectric cap structures 450 can be removed by the chemical mechanical planarization process. The top surfaces of the gate divider rail structures 154 can be coplanar with the top surfaces of the dielectric cap structures 450 after the planarization process. Subsequently, the sacrificial pillar structures 557 can be removed by an etch process (which may be an isotropic or anisotropic etch or ashing for carbon structures) selective to the materials of the dielectric cap structures 450, the ladder-shaped gate electrode lines 52, and the planar insulating spacer layer 208.

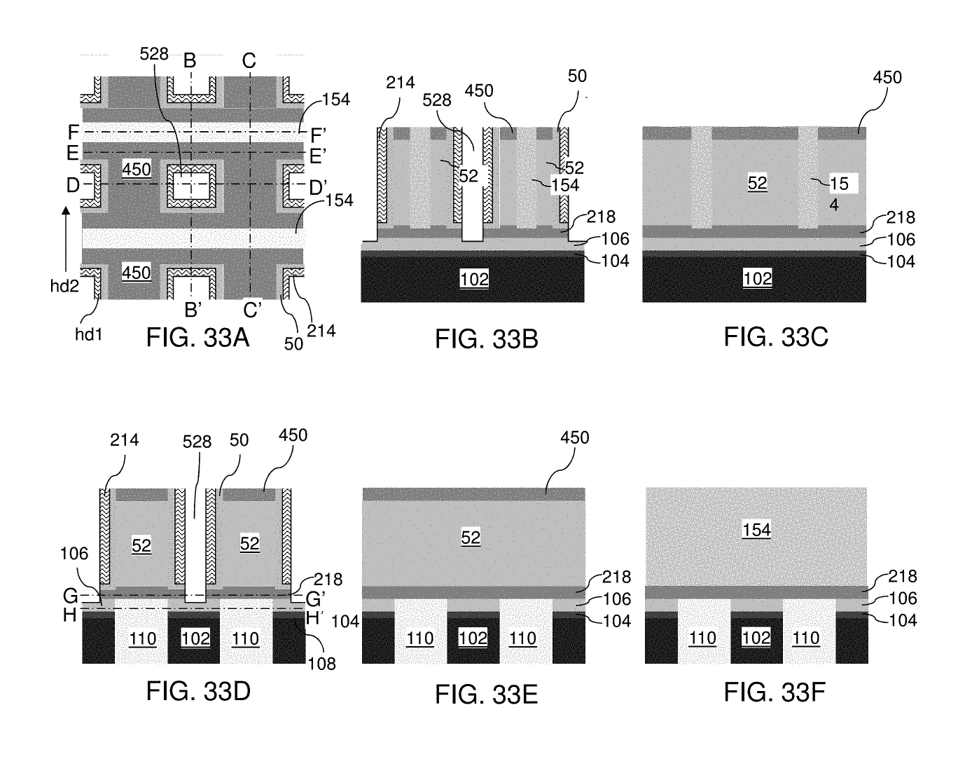

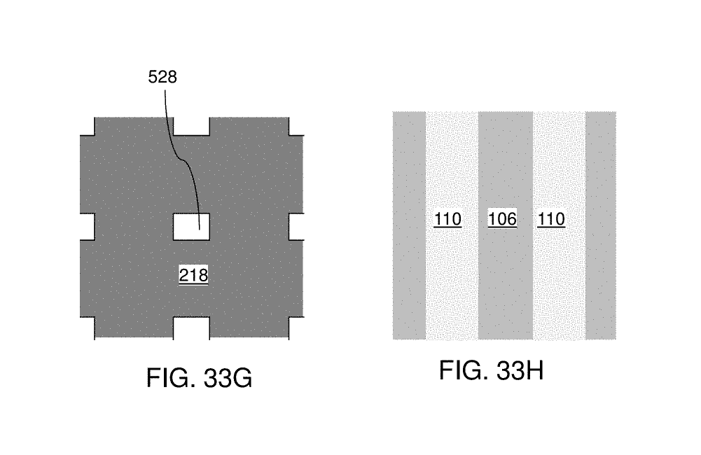

Referring to FIGS. 33A-33H, gate dielectrics 50 and first vertical channel portions 214 can be formed on the second exemplary structure. For example, a continuous gate dielectric layer including at least one dielectric material (such as silicon oxide, silicon oxynitride, a dielectric metal oxide, or a combination thereof) can be formed by a conformal deposition on the sidewalls of the gate electrode lines 52, on physically exposed portions of the top surface of the planar insulating spacer layer 208, on top surfaces of the gate divider rail structures 154, and on the top surfaces and physically exposed sidewalls of the dielectric cap structures 450. In case the material of the gate electrode lines 52 includes a semiconductor material (such as doped polysilicon), at least a portion of the gate dielectrics 50 can be formed by converting surface portions of the gate electrode lines 52 into dielectric material portions by an oxidation process (which may include thermal oxidation or plasma oxidation) and/or a nitridation process (which may include thermal nitridation or plasma nitridation) in lieu of, or in addition to, formation of the continuous gate dielectric layer.

A doped semiconductor material of the second conductivity type that is the opposite of the first conductivity type can be conformally deposited on the continuous gate dielectric layer (for example, by low pressure chemical vapor deposition) to form a conformal doped semiconductor material layer. For example, if the first conductivity type (which is the conductivity type of the doped semiconductor material of the doped semiconductor strips 106) is n-type, the second conductivity type is p-type, and vice versa. The thickness of the conformal doped semiconductor material layer can be in a range from 5 nm to 100 nm, although lesser and greater thicknesses can also be employed.

An anisotropic etch is performed to remove horizontal portions of the conformal doped semiconductor material layer and horizontal portions of the continuous gate dielectric layer. Each remaining vertical portion of the conformal doped semiconductor material layer constitutes a first vertical channel portion 214, which can have a hollow rectangular configuration with a rectangular outer periphery and a rectangular inner periphery. Each remaining portion of the continuous gate dielectric layer (or any discrete equivalents thereof that are formed by conversion of surface portions of the gate electrode lines 52) constitutes a gate dielectric 50. In one embodiment, each gate dielectric 50 has a hollow configuration within a rectangular outer periphery and a rectangular inner periphery. Each first vertical channel portion 214 can be nested inside a respective gate dielectric 50. In one embodiment, the gate dielectrics 50 can have a horizontal “foot” portion that underlies a first vertical channel portion 214. The gate dielectrics 50 are formed on the sidewalls of the rectangular openings within the gate electrode lines 52.

The anisotropic etch can be extended through cavity 528 between the first vertical channel portions 214, optionally with a change in etch chemistry, to etch physically exposed portions of the planar insulating spacer layer 208. Rectangular openings (i.e., extensions of cavities 528) arranged in a two-dimensional periodic array can be formed through the planar insulating spacer layer 208. The planar insulating spacer layer 208 after formation of the array of rectangular openings therethrough is herein referred to as a patterned insulating spacer plate 218. The patterned insulating spacer plate 218 contacts the entire bottom surface of each ladder-shaped gate electrode line 52 within the one-dimensional array of ladder-shaped gate electrode lines 52. A top surface of a doped semiconductor strip 106 is physically exposed within each area of the openings in the patterned insulating spacer plate 218.

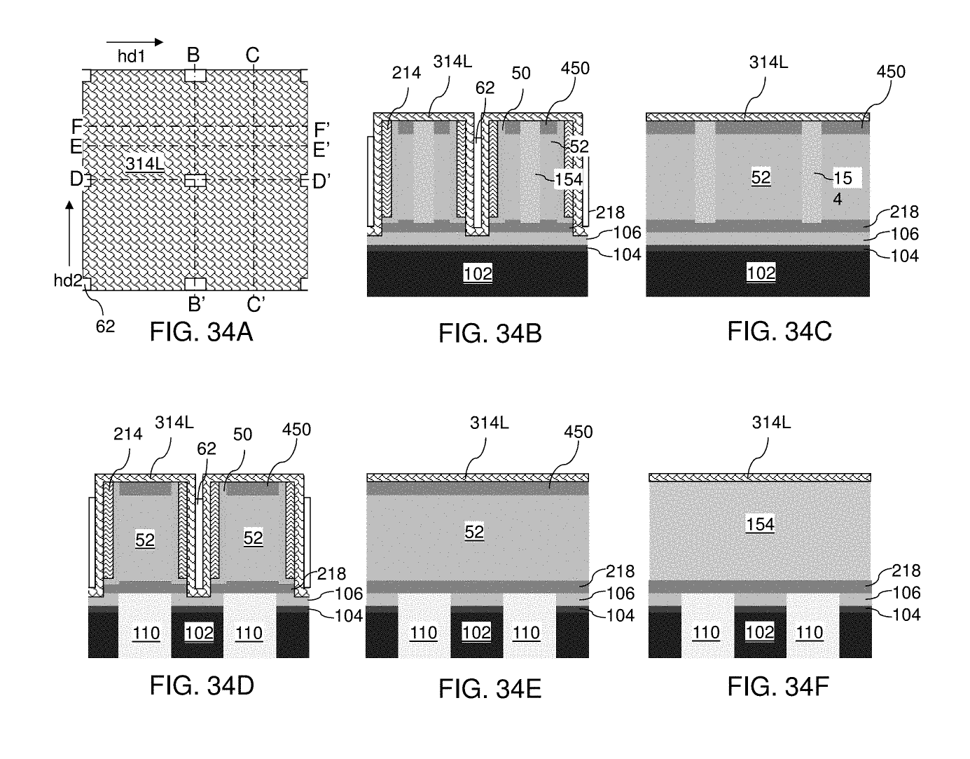

Referring to FIGS. 34A-34F, a doped semiconductor material of the second conductivity type can be deposited in the cavities 528 within the first vertical channel portions 214 by a conformal deposition process such as low pressure chemical vapor deposition. The cavities within the first vertical channel portions 214 can be partially filled with a second vertical channel layer 314L. The thickness of the second vertical channel layer 314L may be selected such that an unfilled cavity is present within each cylindrical portion of the second vertical channel layer 314L that is laterally surrounded by a respective first vertical channel portion 213. In an illustrative example, the thickness of the second vertical channel layer 314L can be in a range from 5 nm to 50 nm, although lesser and greater thicknesses can also be employed.

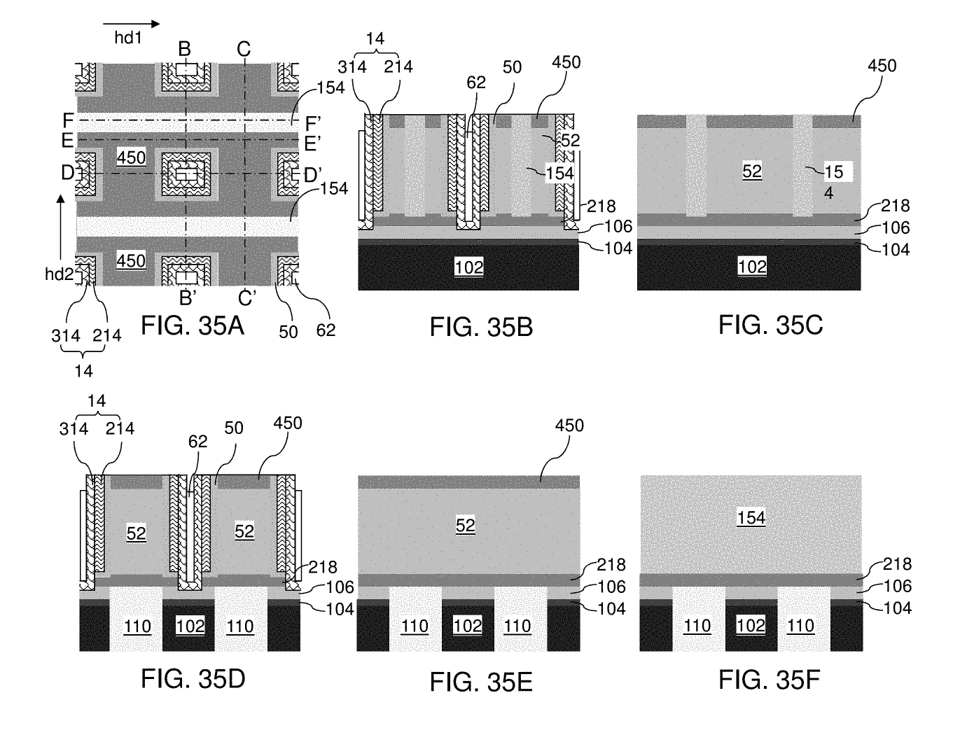

Referring to FIGS. 35A-35F, a dielectric material can be deposited in the cavities that are laterally surrounded by each cylindrical vertical portion of the second vertical channel layer 314L. The dielectric material can include silicon oxide or a flowable oxide material. The dielectric material can be deposited by a conformal deposition process (such as low pressure chemical vapor deposition) or spin coating. A reflow process may be optionally employed to promote filling of the cavities by the dielectric material. Portions of the dielectric material located above the horizontal plane including the top surfaces of the dielectric cap structures 450 can be removed, for example, by a first recess etch. The first recess etch can be prolonged after removal of all portions of the dielectric material from above the horizontal plane including the top surfaces of the dielectric cap structures 450 to vertically recess remaining portions of the dielectric material inside vertical portions of the second vertical channel layer 314L. Each remaining portion of the dielectric material is herein referred to as a dielectric core 62, which can be a rectangular pillar structure. The top surface of each dielectric pillar structure may be located at, or above, the horizontal plane including the interface between the dielectric cap structures 450 and the ladder-shaped gate electrode lines 52.

Horizontal portions of the second vertical channel layer 314L can be removed from above the horizontal plane including the top surfaces of the dielectric cap structures 450 by a second recess etch. The second recess etch can remove the semiconductor material of the second vertical channel layer 314L selective to the materials of the dielectric cap structures 450, the gate divider rail structures 154, and the dielectric cores 62. Each remaining portion of the second vertical channel layer 314L is herein referred to as a second vertical channel portion 314. The second recess etch may be an anisotropic etch or an isotropic etch. If the second recess etch is an anisotropic etch, the top surfaces of the second vertical channel portions 314 can be located at, or immediately below, the height of the top surfaces of the dielectric cap structures 450. If the second recess etch is an isotropic etch (such as a wet etch employing a TMY or KOH solution), the height of the top surfaces of the second vertical channel portions 314 can be located at, or immediately below, the height of the top surfaces of the dielectric cores 62.

Each adjoining pair of a first vertical channel portion 214 and a second vertical channel portion 314 constitutes a vertical semiconductor channel 14. Thus, a vertical semiconductor channel 14 is formed within each of the gate dielectrics 50 by deposition of at least one semiconductor material having a doping of the second conductivity type that is different from the first conductivity type.

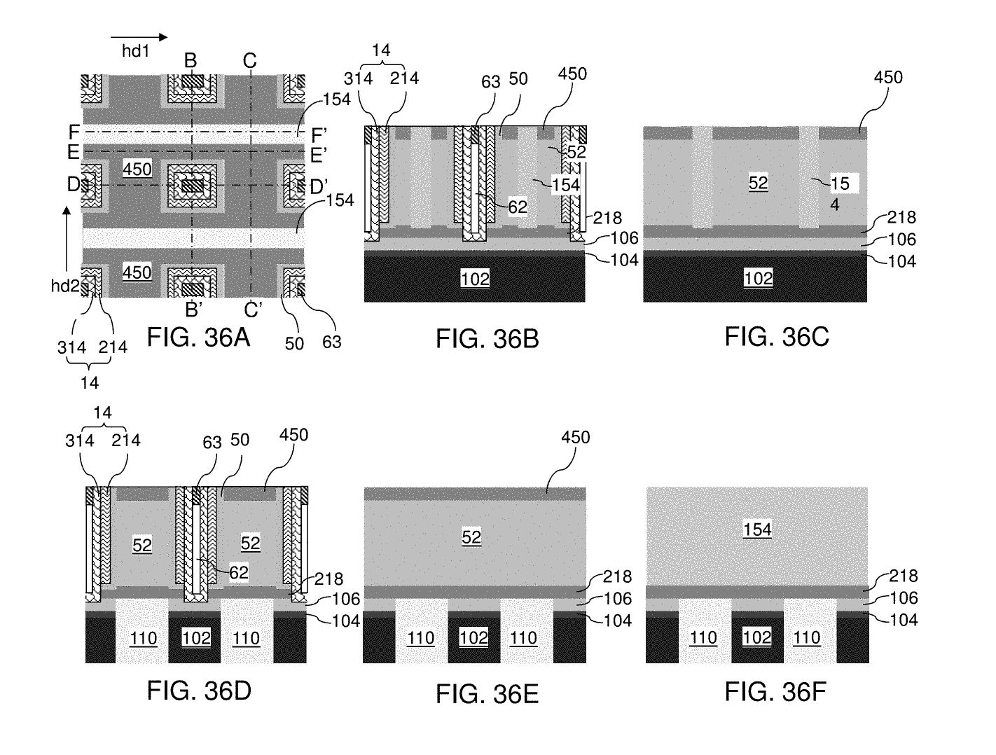

Referring to FIGS. 36A-36F, a doped semiconductor material (such as doped polysilicon) having a doping of the first conductivity type can be deposited in the recesses overlying the dielectric cores 62. Excess portions of the deposited doped semiconductor material can be removed from above the horizontal plane including the top surfaces of the dielectric cap structures 450 by a planarization process, which can include chemical mechanical planarization or a recess etch. Each remaining portion of the deposited doped semiconductor material constitutes a top active region 63 having a doping of the first conductivity type. The top active regions 63 may be source regions or drain regions depending on the operational mode of the vertical field effect transistors to be formed. Each top active region 63 is formed directly on a respective one of the vertical semiconductor channels 14.

Alternative methods can be employed to form the drain regions 63. For example, a doped semiconductor material having a doping of the first conductivity type can be deposited after formation of the dielectric cores 62 and without removing the horizontal portions of the second vertical channel layer 314L from above the horizontal plane including the top surfaces of the dielectric cap structures 450. In this case, the doped semiconductor material can be deposited directly on the physically exposed surfaces of the second vertical channel layer 314L before any portion of the second vertical channel layer 314L is removed. Subsequently, excess portion of the doped semiconductor material having the doping of the first conductivity type and excess portions of the second vertical channel layer 314L can be removed from above the horizontal plane including the top surfaces of the dielectric cap structures 450 employing a same planarization process, which can include chemical mechanical planarization and/or a recess etch. Yet alternatively, an undoped semiconductor material may be deposited in lieu of the doped semiconductor material, and ion implantation of dopants of the first conductivity type can be employed to introduce dopants of the first conductivity type into portions of the semiconductor material overlying the dielectric cores 62. Excess portions of the semiconductor material can be removed employing a planarization process in which the dielectric cap structures 450 can be utilized as stopping structures.

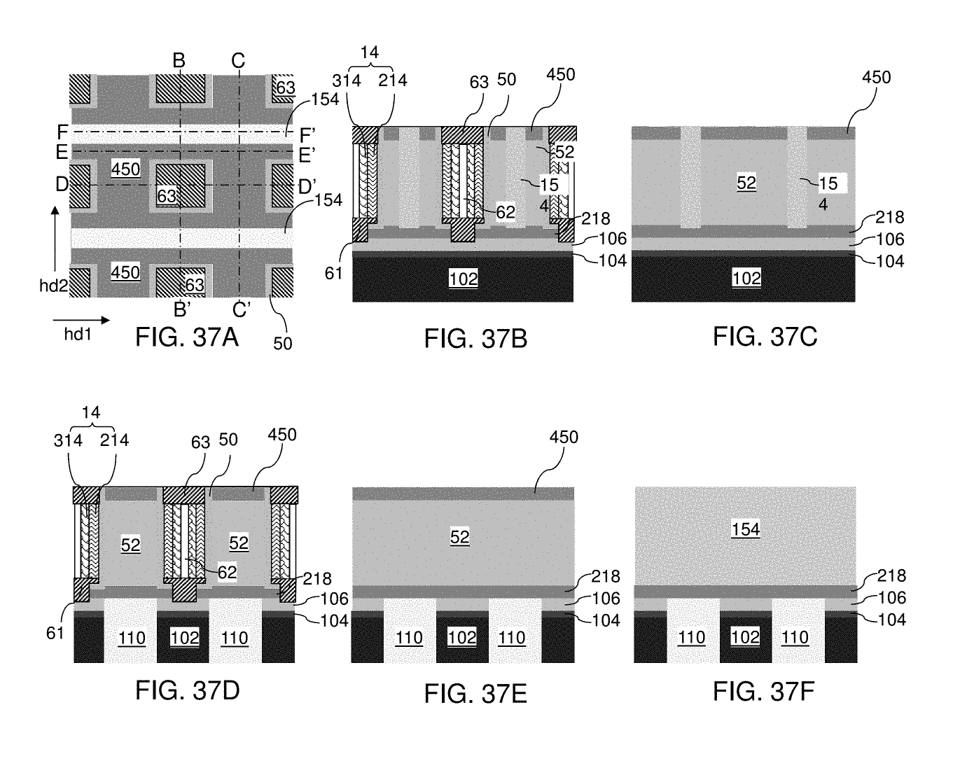

Referring to FIGS. 37A-37F, an anneal process is performed at an elevated temperature to induce outdiffusion of dopants of the first conductivity type from the doped semiconductor strips 106 (i.e., global source or drain lines which are derived from the doped semiconductor material layer 106L as formed at the processing steps of FIGS. 18A and 18B) into lower portions of the vertical semiconductor channels 14. A bottom portion of each vertical semiconductor channel 14 is converted into a bottom local active region 61, which can be a local source region or a local drain region depending on the operational mode of the vertical field effect transistors. For example, if the top active regions 63 are employed as source regions, the bottom active regions 61 can be employed as drain regions, and vice versa. Dopants of the first conductivity type in the top active regions 63 outdiffuse into proximal portions of the vertical semiconductor channels 14 so that the top active regions 63 grow in size. The temperature and the duration of the anneal process can be selected to optimize the vertical overlap between the gate electrode lines 52 and each of the top active regions 63 and the bottom active regions 61.

A two-dimensional array of vertical field effect transistors that are controlled by a one-dimensional array of ladder-shaped gate electrode lines 52 is provided. Each of the ladder-shaped gate electrode lines 52 laterally extends along the first horizontal direction hd1. The bottom active regions 61 of the vertical field effect transistors are electrically connected to a respective one of the conductive rails 102 (e.g., global bit lines for the ReRAM device) that extend along the second horizontal direction hd2.

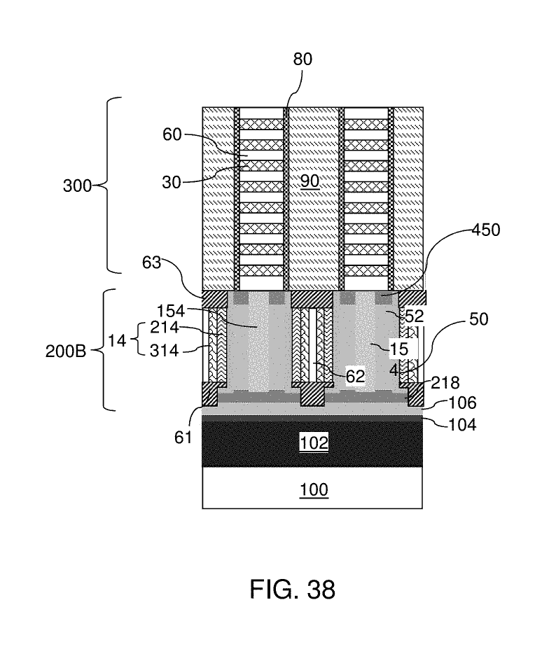

Referring to FIG. 38, a three-dimensional array of memory devices 300 can be formed over the two-dimensional array of vertical field effect transistors 200B. The three-dimensional array of memory devices can be any type of three-dimensional device (e.g., ReRAM devices described above) that can be accessed by a two-dimensional array of vertically extending lines that are electrically shorted to a respective one of the top active regions 63 of the two-dimensional array of vertical field effect transistors 200B

The second exemplary structure can be formed on a substrate 100 including an insulating top surface. After formation of the second exemplary structure, a plurality of alternating stacks (30, 60) of insulating strips 60 and electrically conductive strips 30 can be formed over the two-dimensional array of vertical field effect transistors. Each layer within an alternating stack (30, 60), i.e., each of the insulating strips 60 and the electrically conductive strips 30 in the alternating stack (30, 60), can laterally extend along a horizontal direction, which may be selected from the first horizontal direction hd1 and the second horizontal direction hd2. Each neighboring pair of alternating stacks (30, 60) can be laterally spaced from each other by a line trench. The line trenches can form a one-dimensional array that is repeated along a horizontal direction that is perpendicular to the horizontal direction along which the layers within each alternating stack (30, 60) laterally extend. The line trenches can be filled with a two-dimensional array of dielectric pillar structures that defines a two-dimensional array of pillar cavities (i.e., cavities having a respective pillar shape). Each pillar cavity is laterally bounded by a neighboring pair of alternating stacks (30, 60) along one horizontal direction, and is laterally bounded by a neighboring pair of dielectric pillar structures along another horizontal direction.

Resistive memory elements 80 can be formed on the sidewalls of the pillar cavities, i.e., on the sidewalls of the plurality of alternating stacks (30, 60). The resistive memory elements 80 may be the same as those described above with respect to the first embodiment. Vertical bit lines 90 can be formed in remaining volumes of the pillar cavities. Each vertical bit line 90 can electrically contact a respective one of the top active regions 63, and can be formed between a respective neighboring pair of alternating stacks (30, 60) among the plurality of alternating stacks (30, 60). In one embodiment, the structure formed above the two-dimensional array of vertical field effect transistors can include a three-dimensional array of resistive random access memory (ReRAM) devices.

Referring collectively to all the drawings of the present disclosure, the various embodiments of the present disclosure can provide a semiconductor structure comprising a two-dimensional array of vertical field effect transistors. The two-dimensional array of vertical field effect transistors comprises: a one-dimensional array of ladder-shaped gate electrode lines 52, wherein each of the ladder-shaped gate electrode lines 52 comprises a pair of rail portions 522 that laterally extend along a first horizontal direction hd1 and spaced among one another along a second horizontal direction hd2 and rung portions 524 extending between the pair of rail portions 522 along the second horizontal direction hd2; gate dielectrics 50 located in each opening defined by a neighboring pair of rung portions 524; and vertical semiconductor channels 14 laterally surrounded by a respective one of the gate dielectrics 50 and extending along a vertical direction.

In one embodiment, the semiconductor structure can further comprise: top active regions 63 located at an upper end of a respective one of the vertical semiconductor channels 14; and bottom active regions 61 located at a lower end of a respective one of the vertical semiconductor channels 14.

In one embodiment, the semiconductor structure can further comprise doped semiconductor strips 106 having a doping of a same conductivity type as the bottom active regions 61, contacting a column of the bottom active regions 61 that are arranged along the second horizontal direction hd2, and laterally spaced among one another along the first horizontal direction hd1.

In one embodiment, the semiconductor structure can further comprise a two-dimensional array of insulating spacer plates 118 contacting the rail portions 522 of the one-dimensional array of ladder-shaped gate electrode lines 52 and not contacting the rung portions 524 of the one-dimensional array of ladder-shaped gate electrode lines 52.

In one embodiment, the semiconductor structure can further comprise a patterned insulating spacer plate 218 including rectangular openings within areas of the vertical semiconductor channels 14, contacting each of the doped semiconductor strips 106, and contacting an entire bottom surface of each ladder-shaped gate electrode line 52 within the one-dimensional array of ladder-shaped gate electrode lines 52.

In one embodiment, each of the bottom active regions 61 comprises: an upper portion overlying a horizontal portion (i.e., a foot portion) of a respective one of the gate dielectrics 50; and a lower portion contacting sidewalls of the horizontal portion of the respective one of the gate dielectrics 50 and having a lesser area than the upper portion.

In one embodiment, the semiconductor structure can further comprise gate divider rail structures 154 comprising a dielectric material, laterally extending along the first horizontal direction hd1 and laterally spaced among one another along the second horizontal direction hd2 and contacting sidewalls of a respective neighboring pair of the ladder-shaped gate electrode lines 52.

In one embodiment, the semiconductor structure can further comprise a one-dimensional array of ladder-shaped dielectric cap structures (150, 450) overlying the one-dimensional array of ladder-shaped gate electrode lines 52, wherein sidewalls of the ladder-shaped dielectric cap structures (150, 450) are vertically coincident with underlying sidewalls of the ladder-shaped gate electrode lines 52. As used herein, two sidewalls are vertically coincident if one of the two sidewalls overlies or underlies the other of the two sidewalls and if there exists a vertical plane that includes both of the two sidewalls.

In one embodiment, the semiconductor structure can further comprise an alternating sequence of conductive rails 102 comprising global bit lines and dielectric separator rails 110 that alternate along the second horizontal direction hd2, wherein each of the conductive rails 102 is electrically connected to a respective column of bottom active regions 61 that are arranged along the second horizontal direction hd2.

In one embodiment, the semiconductor structure can further comprise a ReRAM device. The ReRAM device comprises a plurality of alternating stacks (30, 60) of insulating strips 60 and electrically conductive strips 30 overlying the two-dimensional array of vertical field effect transistors, wherein each of the insulating strips 60 and the electrically conductive strips 30 laterally extend along a horizontal direction that is selected from the first horizontal direction hd1 and the second horizontal direction hd2; vertical local bit lines 90 contacting a respective one of the top active regions 63 and vertically extending between a respective neighboring pair of alternating stacks (30, 60) among the plurality of alternating stacks (30, 60); and resistive memory elements 80 located at each intersection between the vertical local bit lines 90 and the plurality of alternating stacks (30, 60).

The vertical semiconductor channels 14 of the vertical field effect transistors are located entirely within a respective one of the rectangular openings 526 in the ladder-shaped gate electrode lines 52. As such, each vertical field effect transistor includes a respective surround gate providing enhanced control of channel mobility compared to vertical field effect transistors including only a pair of gate electrodes on respective two sidewalls of a rectangular semiconductor channel. Further, the vertical field effect transistors including the surrounding gates can provide enhanced sub-threshold voltage characteristics, thereby improving many device characteristics for a three-dimensional memory device.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

1. A semiconductor structure comprising a two-dimensional array of vertical field effect transistors, wherein the two-dimensional array of vertical field effect transistors comprises:
a one-dimensional array of ladder-shaped gate electrode lines, wherein each of the ladder-shaped gate electrode lines comprises a pair of rail portions that laterally extend along a first horizontal direction and spaced among one another along a second horizontal direction and rung portions extending between the pair of rail portions along the second horizontal direction;
gate dielectrics located in each opening defined by a neighboring pair of rung portions;
vertical semiconductor channels laterally surrounded by a respective one of the gate dielectrics and extending along a vertical direction;
top active regions located at an upper end of a respective one of the vertical semiconductor channels; and
bottom active regions located at a lower end of a respective one of the vertical semiconductor channels; wherein each of the bottom active regions comprises:
an upper portion overlying a form horizontal portion of a respective one of the gate dielectrics; and
a lower portion contacting sidewalls of the horizontal portion of the respective one of the gate dielectrics and having a lesser area than the upper portion.

2-3. (canceled)

4. A semiconductor structure comprising a two-dimensional array of vertical field effect transistors wherein the two-dimensional array of vertical field effect transistors comprises:
a one-dimensional array of ladder-shaped gate electrode lines, wherein each of the ladder-shaped gate electrode lines comprises a pair of rail portions that laterally extend along a first horizontal direction and spaced among one another along a second horizontal direction and rung portions extending between the pair of rail portions along the second horizontal direction;
gate dielectrics located in each opening defined by a neighboring pair of rung portions;
vertical semiconductor channels laterally surrounded by a respective one of the gate dielectrics and extending along a vertical direction;
top active regions located at an upper end of a respective one of the vertical semiconductor channels;
bottom active regions located at a lower end of a respective one of the vertical semiconductor channels;
doped semiconductor strips having a doping of a same conductivity type as the bottom active regions, contacting a column of the bottom active regions that are arranged along the second horizontal direction, and laterally spaced among one another along the first horizontal direction; and
a two-dimensional array of insulating spacer plates contacting the rail portions of the one-dimensional array of ladder-shaped gate electrode lines and not contacting the rung portions of the one-dimensional array of ladder-shaped gate electrode lines.

5. A semiconductor structure comprising a two-dimensional array of vertical field effect transistors wherein the two-dimensional array of vertical field effect transistors comprises:
a one-dimensional array of ladder-shaped gate electrode lines, wherein each of the ladder-shaped gate electrode lines comprises a pair of rail portions that laterally extend along a first horizontal direction and spaced among one another along a second horizontal direction and rung portions extending between the pair of rail portions along the second horizontal direction;
gate dielectrics located in each opening defined by a neighboring pair of rung portions;
vertical semiconductor channels laterally surrounded by a respective one of the gate dielectrics and extending along a vertical direction;
top active regions located at an upper end of a respective one of the vertical semiconductor channels;
bottom active regions located at a lower end of a respective one of the vertical semiconductor channels;
doped semiconductor strips having a doping of a same conductivity type as the bottom active regions, contacting a column of the bottom active regions that are arranged along the second horizontal direction, and laterally spaced among one another along the first horizontal direction; and
a patterned insulating spacer plate including rectangular openings within areas of the vertical semiconductor channels, contacting each of the doped semiconductor strips, and contacting an entire bottom surface of each ladder-shaped gate electrode line within the one-dimensional array of ladder-shaped gate electrode lines.

6. (canceled)

7. The semiconductor structure of claim 1, further comprising gate divider rail structures comprising a dielectric material, laterally extending along the first horizontal direction and laterally spaced among one another along the second horizontal direction and contacting sidewalls of a respective neighboring pair of the ladder-shaped gate electrode lines.

8. The semiconductor structure of claim 1, further comprising a one-dimensional array of ladder-shaped dielectric cap structures overlying the one-dimensional array of ladder-shaped gate electrode lines, wherein sidewalls of the ladder-shaped dielectric cap structures are vertically coincident with underlying sidewalls of the ladder-shaped gate electrode lines.

9. The semiconductor structure of claim 1, further comprising an alternating sequence of global bit line conductive rails and dielectric separator rails that alternate along the second horizontal direction, wherein each of the conductive rails is electrically connected to a respective column of bottom active regions that are arranged along the second horizontal direction.

10. The semiconductor structure of claim 9, further comprising a resistive random access memory (ReRAM) device located over the two dimensional array of vertical field effect transistors, the ReRAM device comprising:
a plurality of alternating stacks of insulating strips and electrically conductive strips overlying the two-dimensional array of vertical field effect transistors;
vertical local bit lines electrically contacting a respective one of the top active regions and vertically extending between a respective neighboring pair of alternating stacks among the plurality of alternating stacks; and
resistive memory elements located at each intersection between the vertical local bit lines and the plurality of alternating stacks.

11-20. (canceled)
